(19) United States
(12) Patent Application Publication
(10) Pub. No.: US 2024/0143970 A1
(43) Pub. Date: May 2, 2024

(54) EVOLUTIONAL DEEP NEURAL NETWORKS

(71) Applicant: The Johns Hopkins University, Baltimore, MD (US)

(72) Inventors: Tamer ZAKI, Baltimore, MD (US); Yifan DU, Baltimore, MD (US)

(73) Assignee: The Johns Hopkins University, Baltimore, MD (US)

(21) Appl. No.: 18/278,987

(22) PCT Filed: Mar. 8, 2022
(86) PCT No.: PCT/US2022/019394

§ 371 Date: Aug. 25, 2023

Related U.S. Application Data
(60) Provisional application No. 63/158,167, filed on Mar. 8, 2021.

(51) Int. Cl. G06N 3/04

(52) U.S. Cl. CPC G06N 3/04

(57) ABSTRACT

Some embodiments provide a method of predicting a state of a system that is represented by a partial differential equation. The method comprises training a neural network for an initial state of said system to obtain a set of neural network parameters to provide a spatial representation of said system at an initial time. The method further comprises modifying said parameters for intermediate times between said initial time and a prediction time such that each modified set of parameters is used to provide a respective spatial representation of said system at each corresponding intermediate time using said neural network. The method further comprises modifying said set of parameters to provide a prediction set of parameters that is used to provide a predicted spatial representation of said system at said prediction time using said neural network.

### CROSS-REFERENCE OF RELATED APPLICATION

This application claims priority to U.S. Provisional Application No. 63/158,167, filed Mar. 8, 2021, which is incorporated herein by reference in its entirety.

### BACKGROUND

### 1. Technical Field

Currently claimed embodiments of the invention relate to neural networks, and more particularly evolutional deep neural networks.

### 2. Discussion of Related Art

Computational modeling is useful in many industries, such as, but not limited to, aerospace, automotive, weather prediction, etc. For example, there exists computational physics software for numerous applications, such as, but not limited to, computational fluid dynamics, finite element methods, etc. Many of these applications are very computationally demanding and there thus remains a need for improvements.

Recent machine learning tools, especially deep neural networks, have demonstrated growing success across computational science domains due to their desirable properties. Firstly, a series of universal approximation theorems [9, 7, 10] demonstrate that neural networks can approximate any Borel measurable function on a compact set with arbitrary accuracy provided sufficient number of hidden neurons. This powerful property allows the neural network to approximate any well defined function given enough samples and computational resources. Furthermore, [1] and more recent studies [28, 15] provide the estimations of convergence rate of approximation error on neural network with respect to its depth and width, which subsequently allow the neural network to be used in scenarios with high requirements of accuracy. Secondly, the development of differentiable programming and automatic differentiation allow efficient and accurate calculation of gradients of neural network functions with respect to inputs and parameters. These back-propagation algorithms enable the neural network to be efficiently optimized for specified objectives.

The above properties of neural networks have spurred interest in their application for the solution of PDEs. One general classification of such methods is into two classes: The first focuses on directly learning the PDE operator [14, 16]. In the Deep Operator Network (DeepONet), the input function can be the initial and/or boundary conditions and parameters of the equation that are mapped to the output which is the solution of the PDE at the target spatio-temporal coordinates. In this approach, the neural network is trained using data that are often generated from independent simulations, and which must span the space of interest. The training of the neural network is therefore predicated on the existence of a large number of solutions that may be computationally expensive to obtain, but once trained the network evaluation is computationally efficient [3, 19].

The second class of methods adopts the neural network as basis function to represent a single solution. The inputs to the network are generally the spatio-temporal coordinates of the PDE, and the outputs are the solution values at the given input coordinates. The neural network is trained by minimizing the PDE residuals and the mismatch in the initial/boundary conditions. Such approach dates back to [8], where neural networks were used to solve the Poisson equation and the steady heat conduct equation with nonlinear heat generation. In later studies [13, 2] the boundary conditions were imposed exactly by multiplying the neural network with certain polynomials. In [27], the PDEs are enforced by minimizing energy functionals instead of equation residuals, which is different from most existing methods. In [23], a unified neural network methodology called physics-informed neural network (PINN) for forward and inverse (data assimilation) problems of time dependent PDEs is developed. PINNs utilize automatic differentiation to evaluate all the derivatives in the differential equations and the gradients in the optimization algorithm. The time dependent PDE is realized by minimizing the residuals at randomly generated points in the whole spatio-temporal domain. The cost function has another penalty term on boundary and initial conditions if the PDE problem is forward, and a penalty term on observations for inverse data assimilation problems. The PINN represents the spatio-temporal solution of a PDE as a single neural network, where the behavior in all of space and time is amalgamated in the neural network weights. The temporal evolution, or causality, that is inherent to most time dependent PDEs cannot be explicitly specified in PINNs. In addition, the neural network complexity and the dimension of the optimization space grow as the time horizon increases. As a result, PINN become computationally expensive for long-time predictions. Specifically, for long-time multiscale problems, for example chaotic turbulent flows, the storage requirements and complexity of the optimization become prohibitive. It is also important to note that the solution of PDEs using PINNs relies on a training, or optimization procedure, where the loss function is a balance between equation residuals and initial/boundary data, and the relative weighting of the two elements as well as the time horizon can frustrate the optimization algorithm [26].

As discussed above, the capacity to approximate solutions to partial differential equations (PDEs) using neural network has been a general area of research. However, a key challenge remains for the prediction of the dynamics over very long times, that far exceed the training horizon over which the network was optimized to represent the solution.

### SUMMARY

An embodiment of the present invention is a method of predicting a state of a system that is represented by a partial differential equation, said partial differential equation being a partial differential with respect to time. The method includes training a neural network for an initial state of said system to obtain a set of neural network parameters to provide a spatial representation of said system at an initial time. The method further includes modifying said set of neural network parameters for each of a plurality of intermediate times between said initial time and a prediction time such that each modified set of neural network parameters is used to replace an immediately prior set of neural network parameters in said neural network to provide a respective spatial representation of said system at each corresponding intermediate time using said neural network. The method further includes modifying said set of neural network parameters for said prediction time to provide a prediction set of neural network parameters that is used to replace an immediately prior set of neural network parameters in said neural network to provide a predicted spatial representation of said system at said prediction time using said neural network. Each of said modifying said set of parameters for each intermediate time and for said prediction time is based on a time-dependent property of said partial differential equation without further training of said neural network. The state of said system corresponds to said predicted spatial representation of said system at said prediction time.

Another embodiment of the present invention is a method of solving a nonlinear partial differential equation. The method includes providing a nonlinear partial differential equation that is a function of n variables, said nonlinear partial differential equation being a partial differential with respect to one of said n variables such that said one of said n variables is an evolution variable. The method further includes training a neural network with respect to n-1 of said n variables for an initial value of said evolution variable to obtain a set of neural network parameters to provide an (n-1)-space solution at an initial value of said evolution variable. The method further includes modifying said set of neural network parameters for each of a plurality of intermediate value of said evolution variable between said initial value of said evolution variable and a final value of said evolution variable such that each modified set of neural network parameters is used to replace an immediately prior set of neural network parameters in said neural network to provide a respective (n-1)-space solution of said nonlinear partial differential equation at each corresponding intermediate value of said evolution variable using said neural network. The method further includes modifying said set of neural network parameters for said final value of said evolution variable to provide a solution set of neural network parameters that is used to replace an immediately prior set of neural network parameters in said neural network to provide an (n-1)-space solution of said nonlinear partial differential equation at said final value of said evolution variable using said neural network. Each of said modifying said set of parameters for each intermediate value of said evolution variable and for said final value of said evolution variable is based on an evolution-variable-dependent property of said partial differential equation without further training of said neural network.

Another embodiment of the invention is a computer executable medium having non-transient computer-executable code for predicting a state of a system that is represented by a partial differential equation, said partial differential equation being a partial differential with respect to time. When executed by a computer, the code causes said computer to train a neural network for an initial state of said system to obtain a set of neural network parameters to provide a spatial representation of said system at an initial time. When executed by the computer, the code also causes said computer to modify said set of neural network parameters for each of a plurality of intermediate times between said initial time and a prediction time such that each modified set of neural network parameters is used to replace an immediately prior set of neural network parameters in said neural network to provide a respective spatial representation of said system at each corresponding intermediate time using said neural network. When executed by the computer, the code also causes said computer to modify said set of neural network parameters for said prediction time to provide a prediction set of neural network parameters that is used to replace an immediately prior set of neural network parameters in said neural network to provide a predicted spatial representation of said system at said prediction time using said neural network. Each of said modifying said set of neural network parameters for each intermediate time and for said prediction time is based on a time-dependent property of said partial differential equation without further training of said neural network. The state of said system corresponds to said predicted spatial representation of said system at said prediction time.

Another embodiment of the invention is a computer executable medium having non-transient computer-executable code for solving a nonlinear partial differential equation. When executed by a computer, the code causes said computer to provide a nonlinear partial differential equation that is a function of n variables, said nonlinear partial differential equation being a partial differential with respect to one of said n variables such that said one of said n variables is an evolution variable. When executed by the computer, the code also causes said computer to train a neural network with respect to n-1 of said n variables for an initial value of said evolution variable to obtain a set of neural network parameters to provide an (n-1)-space solution at an initial value of said evolution variable. When executed by the computer, the code also causes said computer to modify said set of neural network parameters for each of a plurality of intermediate value of said evolution variable between said initial value of said evolution variable and a final value of said evolution variable such that each modified set of neural network parameters is used to replace an immediately prior set of neural network parameters in said neural network to provide a respective (n-1)-space solution of said nonlinear partial differential equation at each corresponding intermediate value of said evolution variable using said neural network. When executed by a computer, the code also causes said computer to modify said set of neural network parameters for said final value of said evolution variable to provide a solution set of neural network parameters that is used to replace an immediately prior set of neural network parameters in said neural network to provide an (n-1)-space solution of said nonlinear partial differential equation at said final value of said evolution variable using said neural network. Each of said modifying said set of neural network parameters for each intermediate value of said evolution variable and for said final value of said evolution variable is based on an evolution-variable-dependent property of said nonlinear partial differential equation without further training of said neural network.

Another embodiment of the invention is a system comprising non-transient computer-executable code for predicting a state of a system that is represented by a partial differential equation, said partial differential equation being a partial differential with respect to time. When executed, the code causes said system to train a neural network for an initial state of said system to obtain a set of neural network parameters to provide a spatial representation of said system at an initial time. When executed, the code further causes said system to modify said set of neural network parameters for each of a plurality of intermediate times between said initial time and a prediction time such that each modified set of neural network parameters is used to replace an immediately prior set of neural network parameters in said neural network to provide a respective spatial representation of said system at each corresponding intermediate time using said neural network. When executed, the code further causes said system to modify said set of neural network parameters for said prediction time to provide a prediction set of neural network parameters that is used to replace an immediately prior set of neural network parameters in said neural network to provide a predicted spatial representation of said system at said prediction time using said neural network. Each of said modifying said set of neural network parameters for each intermediate time and for said prediction time is based on a time-dependent property of said partial differential equation without further training of said neural network. The state of said system corresponds to said predicted spatial representation of said system at said prediction time.

Another embodiment of the invention is a system comprising non-transient computer-executable code for solving a nonlinear partial differential equation. When executed, the code causes said system to provide a nonlinear partial differential equation that is a function of n variables, said nonlinear partial differential equation being a partial differential with respect to one of said n variables such that said one of said n variables is an evolution variable. When executed, the code further causes said system to train a neural network with respect to n-1 of said n variables for an initial value of said evolution variable to obtain a set of neural network parameters to provide an (n-1)-space solution at an initial value of said evolution variable. When executed, the code further causes said system to modify said set of neural network parameters for each of a plurality of intermediate value of said evolution variable between said initial value of said evolution variable and a final value of said evolution variable such that each modified set of neural network parameters is used to replace an immediately prior set of neural network parameters in said neural network to provide a respective (n-1)-space solution of said nonlinear partial differential equation at each corresponding intermediate value of said evolution variable using said neural network. When executed, the code further causes said system to modify said set of neural network parameters for said final value of said evolution variable to provide a solution set of neural network parameters that is used to replace an immediately prior set of neural network parameters in said neural network to provide an (n-1)-space solution of said nonlinear partial differential equation at said final value of said evolution variable using said neural network. Each of said modifying said set of neural network parameters for each intermediate value of said evolution variable and for said final value of said evolution variable is based on an evolution-variable-dependent property of said nonlinear partial differential equation without further training of said neural network.

### BRIEF DESCRIPTION OF THE DRAWINGS

Further objectives and advantages will become apparent from a consideration of the description, drawings, and examples.

FIG. 1 compares the structures of a PINN and an EDNN of some embodiments.

FIG. 2 shows the physical domains of a PINN and an EDNN of some embodiments.

FIG. 3 shows an example of schematics for Dirichlet boundary conditions.

FIG. 4 shows an example of a numerical solution and error evaluation of the 2D heat equation using EDNN.

FIG. 5 shows an example of a numerical solution and error evaluation of the linear wave equation using EDNN.

FIG. 6 shows an example of a numerical solution of N-wave formation using EDNN.

FIG. 7 shows an example of a numerical solution of a one-dimensional Kuramoto Sivashinsky equation using EDNN.

FIG. 8 shows an example of error evolution of a KS solution from EDNN against a Fourier spectral solution.

FIG. 9 shows an example comparison of an analytical solution and an EDNN solution of the Taylor Green vortex.

FIG. 10 shows an example of a quantitative evaluation of the EDNN solution of the Taylor Green vortex.

FIG. 11 shows an example of an instantaneous comparison of vorticity from Kolmogorov flow between a spectral method and EDNN.

FIG. 12 shows an example of fully developed turbulent snapshots of velocity components from EDNN calculations.

FIG. 13 shows fully-developed turbulent snapshots and long-time statistics of chaotic Kolmogorov flow from spectral methods and EDNN.

FIG. 14 illustrates an example of a multi-layer machine-trained network used as an EDNN in some embodiments.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed, and other methods developed, without departing from the broad concepts of the current invention. All references cited anywhere in this specification, including the Background and Detailed Description sections, are incorporated by reference as if each had been individually incorporated.

Some embodiments of the current invention can provide new methods and software and improved computational devices to solve the equations of physical processes and/or systems using machine learning techniques. Accordingly, some embodiments of the current invention are directed to deep neural networks that are dynamic, for example, they can predict the evolution of the governing equations.

While various embodiments of the present invention are described below, it should be understood that they are presented by way of example only, and not limitation. Thus, the breadth and scope of the present invention should not be limited by any of the described illustrative embodiments but should instead be defined only in accordance with the following claims and their equivalents.

Some embodiments use an Evolutional Deep Neural Network (EDNN) for the solution of partial differential equations (PDE). The parameters of the EDNN network are trained to represent the initial state of the system only, and are subsequently updated dynamically, without any further training, to provide an accurate prediction of the evolution of the PDE system. In this framework, the EDNN network is characterized by parameters that are treated as functions with respect to the appropriate coordinate and are numerically updated using the governing equations. In some embodiments, by marching the neural network weights in the parameter space, EDNN can predict state-space trajectories that are indefinitely long, which is difficult for other neural network approaches. In some embodiments, boundary conditions of the PDEs are treated as hard constraints, are embedded into the neural network, and are therefore exactly satisfied throughout the entire solution trajectory. Several applications including the heat equation, the advection equation, the Burgers equation, the Kuramoto Sivashinsky equation and the Navier-Stokes equations are solved as examples to demonstrate the versatility and accuracy of EDNN. The application of EDNN in some embodiments to the incompressible Navier-Stokes equation embeds the divergence-free constraint into the network design, so that the projection of the momentum equation to solenoidal space is implicitly achieved. The numerical results verify the accuracy of EDNN solutions relative to analytical and benchmark numerical solutions, both for the transient dynamics and statistics of the system.

The application of EDNN to multiple use cases is contemplated. For example, in some embodiments, EDNN may be applied to the prediction of energy transfer and heat diffusion. As another example, in some embodiments, EDNN may be applied to the prediction of fluid dynamics, including turbulence from low Mach numbers to hypersonic speeds. As still another example, in some embodiments, EDNN may be applied to the solution of population balance equations. These are non-limiting examples which do not preclude the application of EDNN to other use cases involving the solution of PDE.

### 1. Introduction

In the present effort, a new framework of solving time dependent PDEs, which is referred to as an evolutional deep neural network (EDNN), is introduced and demonstrated. The spatial dependence of the solution is represented by the neural network, while the time evolution is realized by evolving, or marching, in the neural network parameter space. In some embodiments, the parameters of an Evolution Deep Neural Networks (EDNN) are viewed as functions in the appropriate coordinate and are updated dynamically, or marched, to predict the evolution of the solution to the PDE for any extent of interest. Various time dependent PDEs are solved using EDNN as examples to demonstrate its capabilities.

In Section 2, network parameter marching is described in detail, accompanied with a description of some embodiments to embed various constraints into the neural network including boundary conditions and divergence-free constraints for Navier-Stokes equations. In Section 3, several examples of time dependent PDEs are solved with a newly established EDNN. Various properties of EDNN including temporal and spatial convergence, and long-time predictions are investigated. Conclusions are summarized in section 4.

### 2. Methodology

Consider a time dependent general nonlinear partial differential equation,

$$\frac{\partial u}{\partial t} - {N}_{x} ( u ) = 0 , x ∈ Ω ⊂ {ℝ}^{d} \qquad ( 1 )$$

where u(x, t)=(u₁, u₂, . . . , uₘ) is a vector function on both space and time, the vector x=(x₁, x₂, . . . , x_{d}) contains spatial coordinates, and [symbol] ₓ is a nonlinear differential operator. In conventional PINNs, a deep neural network representing the whole time-space solution is trained. For larger time horizons, the network complexity must scale accordingly both in terms of its size and also in terms of training cost which involves optimization of the network parameters. Thus, for very long time horizons, the computational complexity becomes intractable. The PINN structure is also not suitable for making predictions beyond the training horizon, or forecasting. In other words, given a trained PINN for a specific time window, further training is required if the solution is required beyond the original horizon.

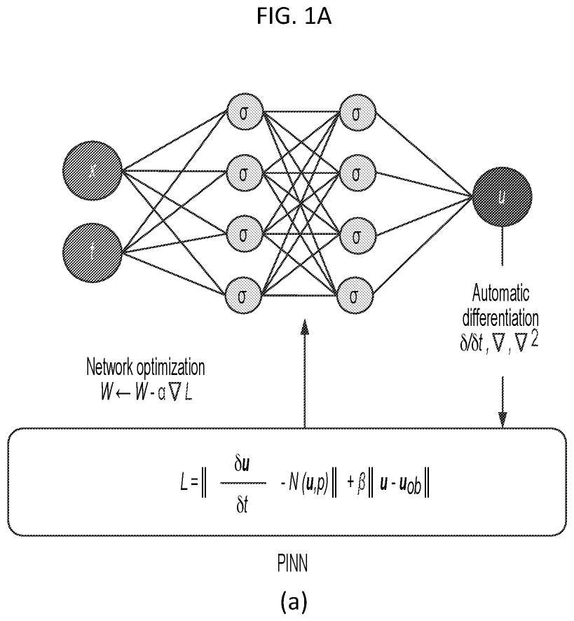

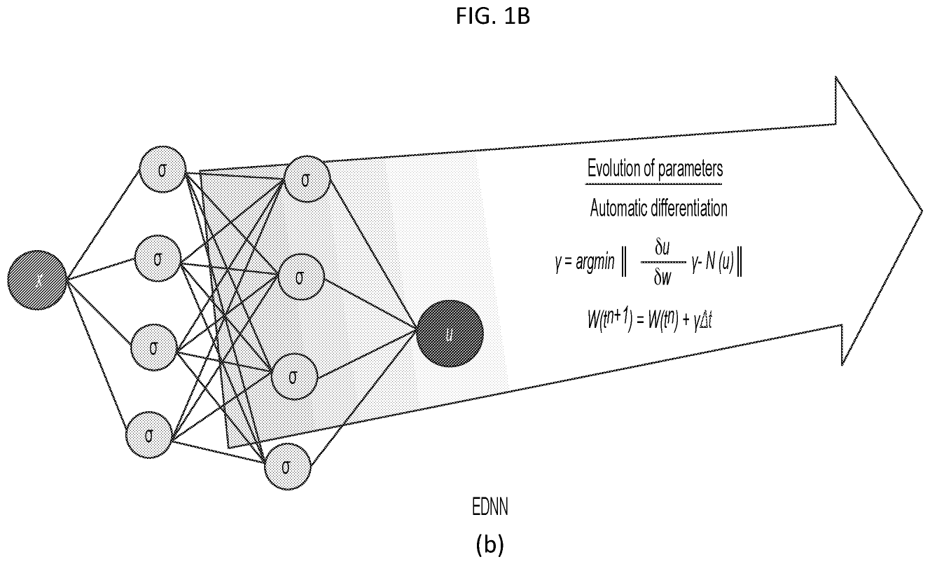

In some embodiments of the present invention, a different perspective is adopted, in which the neural network represents the solution in space only and at a single instant in time, rather than the solution over the entire spatio-temporal domain. Predictions are then made by evolving the initial neural network using the governing equation (1). This new framework of using neural network to solve PDEs is referred to as an Evolutional Deep Neural Network (EDNN). A schematic of the structure of EDNN and its solution domain are shown in FIG. 1, as discussed in further detail below. In this technique, the neural network size need only be sufficient to represent the spatial solution at one time step, yet the network has the capacity to generate the solution for indefinitely long times since its parameters are updated dynamically, or marched, using the governing equations in order to forecast the solution. This technique is equivalent to discretizing equation (1) using the neural network on space and numerical marching in time. It should be noted that the same approach is applicable in any marching dimension, for example along the streamwise coordinate in boundary-layer flows. A key consideration, however, in this new framework is the requirement that boundary conditions are strictly enforced.

FIG. 1 compares the structures of a PINN and an EDNN of some embodiments. Panel (a) shows the structure and training logic of PINNs, where a cost function containing equation residual and data observations is formed. The network is updated by gradient-descent type optimization. Panel (b) shows the evolution of EDNN. The network is evolved with a direction λ calculated from the PDE. The update of neural network parameters represent the time evolution of the solution.

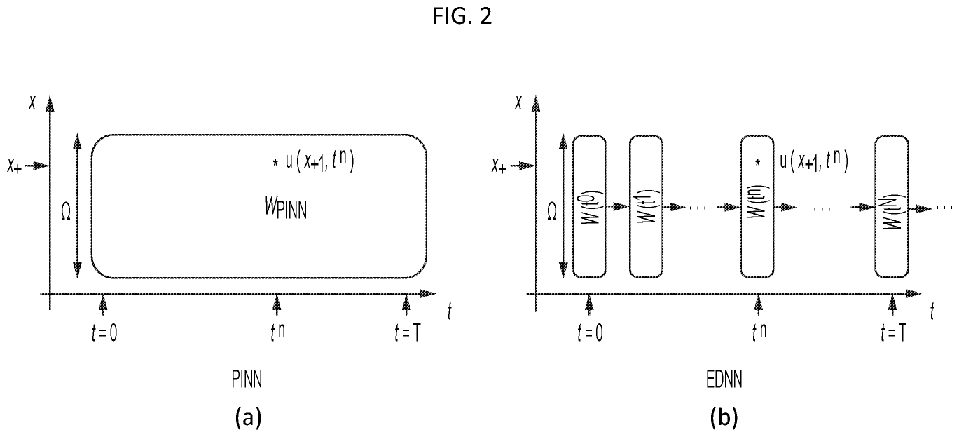

FIG. 2 shows the physical domains of a PINN and an EDNN of some embodiments. Panel (a) shows how PINN represents the solution in the whole spatial-time domain as a neural network and performs training on it. Panel (b) shows how the neural network in EDNN only represents the solution on spatial domain at one time step. The time evolution of one single network creates the time trajectory of solution. The network can be evolved indefinitely.

Section 2.1 introduces a detailed algorithm for evolving the neural network parameters in some embodiments. In section 2.2, the approach of some embodiments for enforcing linear constraints on the neural network is discussed, with application to sample boundary conditions. An example of enforcing the divergence-free constraint is also introduced, which will be adopted in the numerical examples using the two-dimensional Navier Stokes equations.

### 2.1. Evolutional Network Parameters

Consider an example of a fully connected neural network defined by,

gₗ₊₁(gₗ)=σ(Wₗgₗ+bₗ), (2)
where l∈{0, 1, . . . , L} is the layer number, gₗ represents the vector containing all neuron elements at the l^{th} layer of the network, Wₗ and bₗ represent the kernel and bias between layers l and l+1, and σ(·) is the activation function acting on a vector element-wise. Inputs to this neural network are the spatial coordinates of the PDE (1),

g₀=x=(x₁, x₂, . . . , x_{d}).

The neural network parameters may be considered as functions of time Wₗ(t) and bₗ(t) so that the whole network is time dependent, and [symbol] (t) denotes the vector containing all parameters in the neural network. The output layer g_{L+1} approximation û of the solution to the PDE (1) is,

g_{L+1}=û(x, [symbol] (t))=(û₁, û₂, . . . , ûₘ).

The dependence of û on time is implicitly contained in the neural network parameter [symbol] (t). The time derivative of solution û can be calculated according to,

$$\frac{\partial \hat{u}}{\partial t} = \frac{\partial \hat{u}}{\partial 𝒲} \frac{\partial 𝒲}{\partial t} .$$

At each time instant, the time derivative ∂W/∂t can be approximated by solving,

$$\frac{\partial 𝒲}{\partial t} = arg min 𝒥 ( γ ) , where 𝒥 ( γ ) = {\int }_{Ω} {‖ \frac{\partial \hat{u}}{\partial 𝒲} γ - 𝒩 ( \hat{u} ) ‖}_{2}^{2} d x , \qquad ( 3 )$$

where ∥·∥₂ is the vector 2-norm in [symbol] ^{m}. The first-order optimality condition of problem (3) yields,

$$∇ γ𝒥 ( {γ}_{opt} ) = ( {\int }_{Ω} \frac{\partial \hat{u}}{\partial 𝒲} \frac{\partial {\hat{u}}^{T}}{\partial 𝒲} dx ) {γ}_{opt} - ( {\int }_{Ω} \frac{\partial {\hat{u}}^{T}}{\partial 𝒲} 𝒩 ( \hat{u} ) dx ) = 0. \qquad ( 4 )$$

The optimal solution γₒₚₜ can be approximated by \hat{γ}ₒₚₜ which is the solution to,

J^{T}J_{\hat{γ}}_{ₒₚₜ}=J^{T}N. (5)

In equation (5), J is the neural network gradient and N is the PDE operator evaluated at a set of spatial points,

$${( J )}_{ij} = \frac{\partial {u}^{i}}{\partial {𝒲}_{j}} , {( N )}_{i} = 𝒩 ( {u}^{i} ) , \qquad ( 6 )$$

where i=1, 2, . . . , Nᵤ is the index of the collocation point, and j=1, 2, . . . , [symbol] is the index of the neural network parameter. The elements in J and N are calculated through automatic differentiation. It can be shown that as the number of collocation points Nᵤ→∞, the following holds:

$$\frac{1}{{N}_{u}} {J}^{T} J \to ( {\int }_{Ω} \frac{\partial \hat{u}}{\partial 𝒲} \frac{\partial {\hat{u}}^{T}}{\partial 𝒲} dx ) , \frac{1}{{N}_{u}} {J}^{T} N \to ( {\int }_{Ω} \frac{\partial {\hat{u}}^{T}}{\partial 𝒲} 𝒩 ( \hat{u} ) dx ) . \qquad ( 7 )$$

The solution of equation (5) is an approximation of the time derivative of [symbol] . Two techniques that can be utilized to solve (5) are direct inversion and optimization. By using the solution from last time step as initial guess, using optimization accelerates the calculations compared to direct inversion. Both techniques give numerical solutions with satisfactory accuracy. An explicit time discretization scheme can be used in some embodiments to perform time marching, for example forward Euler,

$$\frac{{𝒲}^{n + 1} - {𝒲}^{n}}{Δ t} = {\hat{γ}}_{opt}^{n} , \qquad ( 8 )$$

where n is the index of time step, and Δt is the time step size. As another example, for better temporal accuracy, the widely adopted 4^{th} order Runge-Kutta scheme can be used,

[symbol]

ⁿ⁺¹= [symbol] ⁿ+(⅙k₁+⅓k₂+⅓k₃+⅙k₄)Δt, (9)
where k₁ to k₄ are given by,

$${k}_{1} = {\hat{γ}}_{opt} ( {𝒲}^{n} ) \qquad ( 10 )$$

$${k}_{2} = {\hat{γ}}_{opt} ( {𝒲}^{n} + {k}_{1} \frac{Δ t}{2} )$$

$${k}_{3} = {\hat{γ}}_{opt} ( {𝒲}^{n} + {k}_{2} \frac{Δ t}{2} )$$

$${k}_{4} = {\hat{γ}}_{opt} ( {𝒲}^{n} + {k}_{3} Δ t ) .$$

The initial condition [symbol] (0)= [symbol] ₀ can be evaluated through training the neural network with initial data. The cost, or loss, function of this training is,

[symbol]

₀( [symbol] ⁰)=½Σᵢ₌₀^{N}^{ᵤ}∥û(xⁱ, [symbol] ⁰)−u(xⁱ, t=t⁰)∥_{2′}² (11)
where i=1, 2, . . . , Nᵤ represents the index of collocation points. After minimizing (11), the initial condition [symbol] (0) can be used in the ordinary differential equation (3) to solve for the solution trajectory [symbol] (t). The solution of equation (1) then can be calculated at arbitrary time t and space point x by evaluating the neural network using weights [symbol] (t) and input coordinates x.

### 2.2. Embedded Constraints

In this example, a general framework is described to embed linear constraints into neural networks in some embodiments. Denote by [symbol] and [symbol] Banach spaces, and [symbol] as the neural network function class that is to be constrained. A general linear constraint on u∈ [symbol] can be written as follows:

[symbol]

u=0, u∈ [symbol] , (12)
where [symbol] → [symbol] is a linear operator on [symbol] . In conventional deep learning frameworks for solving PDEs, this constraint is realized by minimizing the following functional,

[symbol]

_{A}=∥ [symbol] u [symbol] , u∈ [symbol] , (13)
where ∥· [symbol] , represents the norm corresponding to space [symbol] . This only approximately enforces the linear constraint (12), and the accuracy of the realization of the constraint depends on the relative weighting between the constraint and other objectives of the training, such as satisfying the governing equations or matching of observation data.

Instead of minimizing (13), a novel general approach is sought in some embodiments to exactly enforce linear constraints. Consider another linear operator [symbol] → [symbol] as an auxiliary operator for the realization of constraint (12). The operator G satisfies,

[symbol]

∘ [symbol] (v)=0, v∈ [symbol] ′, (14)
where v is the auxiliary neural network function for the realization of constraint [symbol] . The function space [symbol] ′⊂ [symbol] is the neural network function class corresponding to v. A sufficient condition of equation (14) is,

imag( [symbol] )⊆ker( [symbol] ). (15)

The problem of enforcing linear constraint (12) is thus transformed to the construction of operator [symbol] and the neural network function class [symbol] ′ that satisfies (15). The newly constructed function û= [symbol] (v) satisfies the linear constraint [symbol] (û)=0. In this way, the linear constraint can be enforced exactly along the solution trajectory. Three examples are given below, with different embodiments that use periodic boundary conditions, homogeneous Dirichlet boundary conditions, and a divergence-free condition, respectively.

### 2.2.1. Periodic Boundary Conditions

The treatment of periodic boundary conditions for the solution of PDE using neural network has been investigated in previous research [29]. In most of existing techniques, input coordinates x are replaced with sin (x) and cos (x) to guarantee periodicity. An example of the novel general framework of some embodiments is discussed here for linear constraints on neural networks.

Consider a one-dimensional interval Ω=[0,2π]. The aim is to construct a class of functions that exactly satisfies periodicity on Ω. The linear operator Ap corresponding to periodicity on Ω is,

[symbol]

ₚ(ƒ)=ƒ(0)−ƒ(2π). (16)

Choose v∈ [symbol] ^{2,1} as the auxiliary function, where [symbol] ^{d,q} is the neural network function class with input dimension d and output dimension q. The auxiliary operator [symbol] ₚ is constructed as,

[symbol]

ₚ(v)(x)=v(sin (x), cos (x)). (17)

It can be easily verified that [symbol] ₚ∘ [symbol] ₚ(v)=0. Examples that involve periodic boundary conditions will be discussed in § 3.2, § 3.3 and § 3.4.

### 2.2.2. Dirichlet Boundary Conditions

The homogeneous Dirichlet boundary condition is commonly adopted in the study of PDEs and in applications. The constraint operator [symbol] is the trace operator T: H¹(Ω)→L²(∂Ω), which maps an H¹(Ω) function to its boundary part. The corresponding auxiliary operator [symbol] _{T} is not unique. For example, the following construction of [symbol] _{T} not only guarantees that the homogeneous Dirichlet boundary condition is satisfied, but also provides smoothness properties of the solution,

$${𝒢}_{T} v = v - {\int }_{\partial Ω} \frac{\partial θ}{\partial n} ( x , y ) v ( y ) dy , \qquad ( 18 )$$

where θ is the Green's function of Poisson equation on the domain Ω, and n is the outward unit normal to the boundary. The operator [symbol] _{T} maps any function ƒ∈H¹(Ω) to a function with zero values on the boundary. However, this construction of [symbol] _{T} is not ideal. If v is a neural network function, then any single evaluation of v(x₀) at point x₀∈Ω requires computing the integral

$${\int }_{\partial Ω} \frac{\partial Θ}{\partial n}$$

(x₀, y)v(y)dy, which is computationally expensive.

Instead, a computationally efficient technique is used in some embodiments to enforce the Dirichlet condition on a domain with an arbitrary boundary, which can be demonstrated using a two-dimensional example. The construction is easily extended to higher dimensions, however.

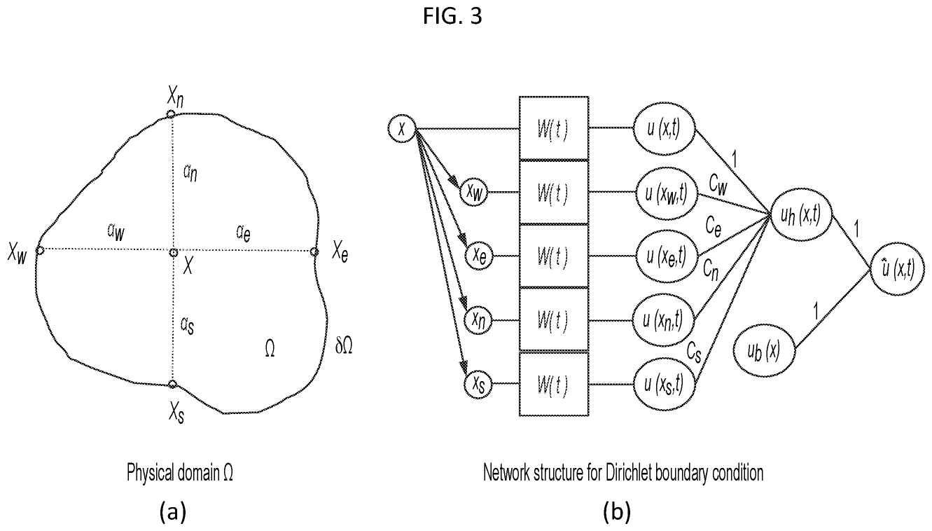

In some embodiments, a neural network with homogeneous boundary conditions can be created from an inhomogeneous network by cancelling its boundary values. For illustration, FIG. 3 shows, in panel (a), a two-dimensional arbitrary domain Ω. An arbitrary point in Ω is denoted x∈Ω⊂ [symbol] ². Horizontal and vertical rays emanating from x intersect the boundary ∂Ω at xₑ, x_{w}xₙ and xₛ, with corresponding distances aₑ, a_{w}aₙ and aₛ, which are all a function of x. Panel (b) shows the structure of a neural network that enforces the boundary conditions. The output uₕ(x, t) is a neural network function with homogeneous Dirichlet boundary conditions,

uₕ(x)= [symbol] _{T}v(x)=v(x)+cₑv(xₑ)+c_{w}v(x_{w})+cₙv(xₙ)+cₛv(xₛ), (19)
where v is a neural network that has non-zero boundary values. The coefficients cₑ, c_{w}, cₙ and cₛ are,

$${c}_{e} = - \frac{{a}_{w} {a}_{n} {a}_{s}}{{a}_{w} {a}_{n} {a}_{s} + {a}_{e}} , \qquad ( 20 )$$

$${c}_{w} = - \frac{{a}_{e} {a}_{n} {a}_{s}}{{a}_{e} {a}_{n} {a}_{s} + {a}_{w}} ,$$

$${c}_{n} = - \frac{{a}_{w} {a}_{e} {a}_{s}}{{a}_{w} {a}_{e} {a}_{s} + {a}_{n}} ,$$

$${c}_{s} = - \frac{{a}_{w} {a}_{e} {a}_{n}}{{a}_{w} {a}_{e} {a}_{n} + {a}_{s}} .$$

The choice of the above construction can be motivated by considering, for example, cₑ(aₑ, a_{w}, aₙ, aₛ) which satisfies,

cₑ(0, a_{w}, aₙ, aₛ)=−1,

cₑ(aₑ, 0, aₙ, aₛ)=cₑ(aₑ, a_{w}, 0, aₛ)=cₑ(aₑ, a_{w}, aₙ, 0)=0

∀aₑ, a_{w}, aₙ, aₛ. (21)

Equation (20) is one example that satisfies such conditions. Once uₕ(x, t) is obtained, in some embodiments an inhomogeneous Dirichlet condition can be enforced on the network by adding u_{b}(x), which may be an analytical function or may be provided by another neural network. The final û(x, t) is the neural network solution that satisfies the Dirichlet boundary conditions. Examples where these conditions are applied will be discussed in § 3.1.

FIG. 3 shows an example of schematics for Dirichlet boundary conditions. Panel (a) shows the physical domain for Dirichlet boundary conditions, that includes all relevant geometric quantities including xₑ, x_{w}, xₙ, xₛ and aₑ, aₑ, aₑ, aₑ corresponding to point x. Panel (b) shows the network structure for Dirichlet boundary conditions. In other words, panel (b) illustrates how the geometrical quantities from panel (a) are used to construct a network satisfying a certain Dirichlet boundary condition.

### 2.2.3. Divergence-free

The divergence-free constraint is required for enforcing continuity in incompressible flow fields. For this constraint, the operator [symbol] is the divergence operator div: H¹(Ω; [symbol] ^{m})→L²(Ω). The dimension of the solution domain dim (Ω)=d is assumed to be the same as the dimension m of the solution vector. In addition, [symbol] ^{d,q} denotes the neural network function class with input dimension d and output dimension q. In different embodiments, the operator [symbol] _{div} corresponding to [symbol] can be constructed in different ways depending on d.

In some embodiments, d=2: v∈ [symbol] ^{2,1}⊂H²(Ω, [symbol] ) is the auxiliary neural network function. The auxiliary operator [symbol] _{div} is constructed as:

$${𝒢}_{div} ( v ) = ( \begin{matrix}\partial v / \partial y \\ - \partial v / \partial x\end{matrix} ) . \qquad ( 22 )$$

In the fluid mechanics context v is the stream function, [symbol] _{div} is the mapping from stream function to velocity field for two-dimensional flow.

In some embodiments, d=3: v∈ [symbol] ^{3,3}⊂.H²(Ω, [symbol] ³) is the auxiliary neural network function. The auxiliary operator [symbol] _{div} is constructed as:

[symbol]

_{div}(v)=∇×v. (23)

An example of incompressible two-dimensional flow will be presented in § 3.4.

### 3. Numerical Results

In this section, examples of different types of PDEs are evolved using EDNN to demonstrate its capability and accuracy for different embodiments. In § 3.1 the two-dimensional time-dependent heat equation is solved, and the convergence of EDNN to the analytical solution is examined. In § 3.2, the one-dimensional linear wave equation and inviscid Burgers equation are solved to demonstrate that EDNN is capable to represent transport, including the formation of steep gradients in the nonlinear case. In both § 3.1 and § 3.2, an examination is provided of the effect of the spatial resolution, and correspondingly the network size, on the accuracy of network prediction. The influence of the time resolution is discussed in connection with the Kuramoto-Sivashinsky (KS, § 3.3) and the incompressible Navier-Stokes (NS, § 3.4) equations, which are nonlinear and contain both advection and diffusion terms. The KS test cases (§ 3.3) are used to examine the ability of EDNN in some embodiments to accurately predict the bifurcation of solutions, relative to benchmark spectral discretization.

For the incompressible NS equations (§ 3.4), predictions of the Taylor-Green flow are compared to the analytical solution and a comprehensive temporal and spatial resolution test is provided for some embodiments. The Kolmogorov flow is also simulated, starting from laminar and turbulent initial conditions. EDNN can in some embodiments predict the correct trajectory starting from the laminar state, and accurately predict long-time flow statistics in the turbulent regime.

In all the following examples, a tanh activation function is used, except for the Burgers equation where a relu activation function is used. The optimization of the neural network weights for the representation of initial condition is performed in this example using stochastic gradient descent.

### 3.1. Parabolic Equations

Using the methodology introduced in § 2, the two-dimensional heat equation,

$$\frac{\partial u}{\partial t} = v ( \frac{{\partial }^{2} u}{\partial {x}^{2}} + \frac{{\partial }^{2} u}{\partial {y}^{2}} ) , ( x , y ) ∈ Ω = {[ - π , π ]}^{2} , \qquad ( 24 )$$

can be solved with boundary and initial conditions,

u(x, y, t=0)=sin (x) sin (y)

u=0 on ∂Ω. (25)

By appropriate choice of normalization, the heat diffusivity can be set to unity, v=1.

In this example, the parameters for linear heat equation calculations using EDNN of two tests, denoted 1h and 2h, are provided in Table 1. In both cases, the network is comprised of L=4 hidden layers, each with n_{L} neurons. The smaller number of neurons is adopted for a lower number of collocation points, while the higher value is for a finer spatial resolution.

TABLE 1

| Case | L | n_{L} | Nₓ | N_{y} | ∈₀ | Δt | vΔt/Δx² |
|---|---|---|---|---|---|---|---|
| 1 h | 4 | 20 | 65 | 65 | 6.8 × 10⁻³ | 1 × 10⁻³ | 0.10 |
| 2 h | | 30 | 129 | 129 | 5.1 × 10⁻³ | 1 × 10⁻³ | 0.42 |

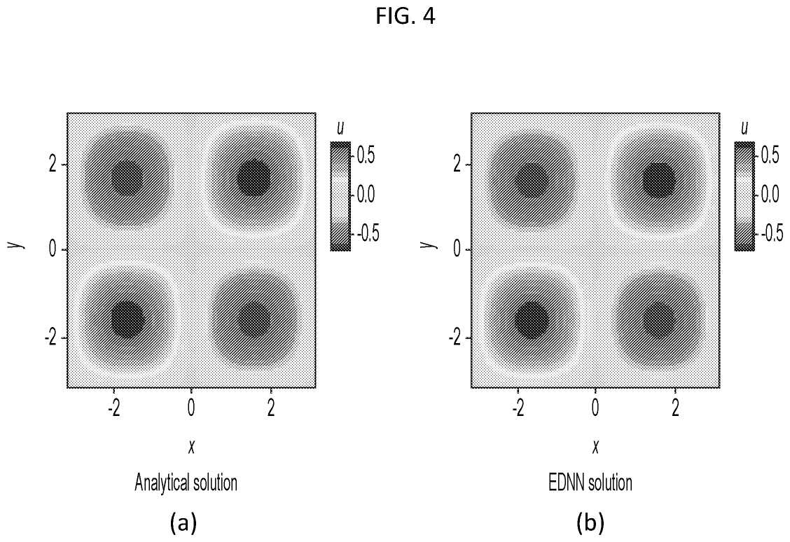

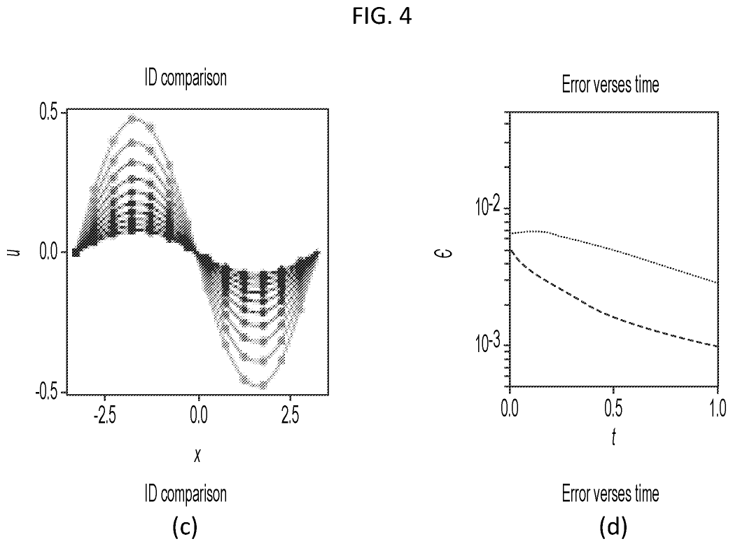

The predictions of EDNN from case 1h is compared to the analytical solution in FIG. 4. The two-dimensional contours predicted by EDNN display excellent agreement with the true solution at t=0.2. Panel (c) shows a comparison of the EDNN and true solutions along a horizontal line (y=1) at different time instances. Throughout the evolution, the EDNN solution shows good agreement with the analytical result.

The instantaneous prediction error is evaluated,

$$ϵ = \frac{{‖ \hat{u} ( t ) - u ( t ) ‖}_{2}}{{‖ u ( 0 ) ‖}_{2}} , \qquad ( 26 )$$

and reported in panel (d) of FIG. 4. The size of neural network for case 2h is larger than case 1h, thus the initial condition of case 2h can be better represented compared to that of case 1h, the error of which is quantitatively evaluated (ϵ₀ in Table 1). The error ϵ of both cases in panel (d) decays monotonically with respect to time, which indicates that the discretization adopted for both cases is stable. One important thing to notice is that spatial refinement of collocation points and larger neural network lead to more accurate solution throughout the evolution.

FIG. 4 shows an example of a numerical solution and error evaluation of the 2D heat equation using EDNN. Panel (a) shows the true (analytical) solution and panel (b) shows the EDNN solution (case 2h) contour at t=0.2. Panel (c) shows the comparison between the true solution and the EDNN solution (case 1h) at different time on a 1-D section at y=1.0, where the data points are the true solution, and the solid line is the EDNN solution. Panel (d) shows the error of EDNN solution with respect to time for different cases, where the dotted line is case 1h, and the dashed line is case 2h.

### 3.2. Hyperbolic Equations

In this example, EDNN is applied to a solution of the one-dimensional linear advection equation and the one-dimensional Burgers equation in order to examine its basic properties for a hyperbolic PDE. The linear case is governed by,

$$\frac{\partial u}{\partial t} + c \frac{\partial u}{\partial x} = 0 , x ∈ [ - 1 , 1 ] , c = 1. \qquad ( 27 )$$

The initial condition is a sine wave,

u(x, 0)=−sin (πx), (28)
and periodicity is enforced in the streamwise direction. EDNN predictions will be compared to the analytical solution,

u=−sin (π(x−ct)). (29)

The parameters of the linear wave equation calculations using EDNN for this example are provided in Table 2 (cases 1lw and 2lw). In both cases, the EDNN architecture is comprised of four layers (L=4) each with either 10 (case 1lw) or 20 (case 2lw) neurons. The number of solution points is increased with the network size, while the timestep is held constant.

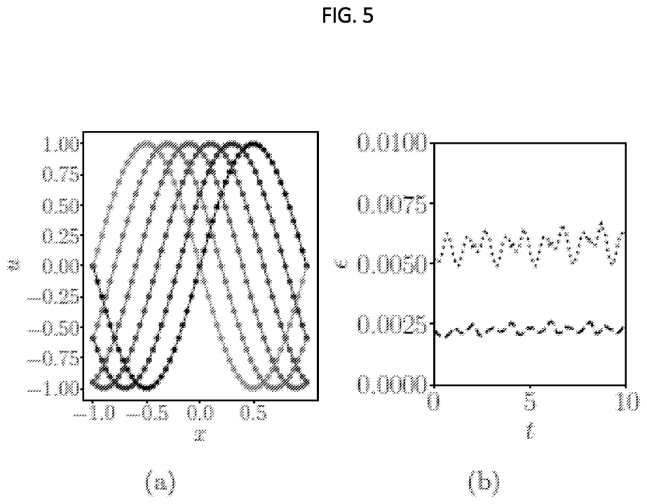

The EDNN prediction (case 2lw) and the analytical solution are plotted superposed in panel (a) of FIG. 5, and show good agreement. The root-mean-squared errors in space ∈ are plotted as a function of time in panel (b), and demonstrates that the solution trajectories predicted by EDNN maintain very low level of errors. Note that the errors maintain their initial values, inherited from the network representation of the initial condition, and are therefore smaller for the larger network that provides a more accurate representation of the initial field. In addition, the errors do not amplify in time, but rather oscillate with smaller amplitude as the network size is increased. This trend should be contrasted to conventional discretizations where, for example, diffusive errors can lead to decay of the solution and an amplification of errors in time.

TABLE 2

| Case | L | n_{L} | Nₓ | Δt |
|---|---|---|---|---|
| 1lw | 4 | 10 | 500 | 1 × 10⁻³ |
| 2lw | | 20 | 1000 | 1 × 10⁻³ |
| 1b | 4 | 20 | 1000 | 1 × 10⁻³ |

FIG. 5 shows an example of a numerical solution and error evaluation of the linear wave equation using EDNN. Panel (a) shows the spatial solution of case 2lw every 0.2 time units, where the data points represent the true solution, and the solid line represents the EDNN solution. Panel (b) shows the relative error on the solution, for case 1lw (dotted line) and case 2lw (dashed line).

The same EDNN for the linear advection equation can be adapted in some embodiments for the non-linear Burgers equation. The formation of shocks and the capacity of NN to capture them (e.g., using different activation functions) is described elsewhere [18]. For the present scope, one option is to introduce a viscous term to avoid the formation of discontinuities in the solution [14]; Since the heat equation has already been simulated in the previous example, here the inviscid form of the Burgers equation is retained and its evolution simulated short of the formation of the N-wave. The equation,

$$\frac{\partial u}{\partial t} + u \frac{\partial u}{\partial x} = 0 , x ∈ [ - 1 , 1 ] \qquad ( 30 )$$

is solved with the initial condition,

u(x, 0)=−sin (πx), (31)
with periodic boundary conditions on the given interval [−1, 1]. The analytical solution is given implicitly by the characteristic equation,

u=−sin (π(x−ut)). (32)

This expression can be solved using a Newton method to obtain a reference solution.

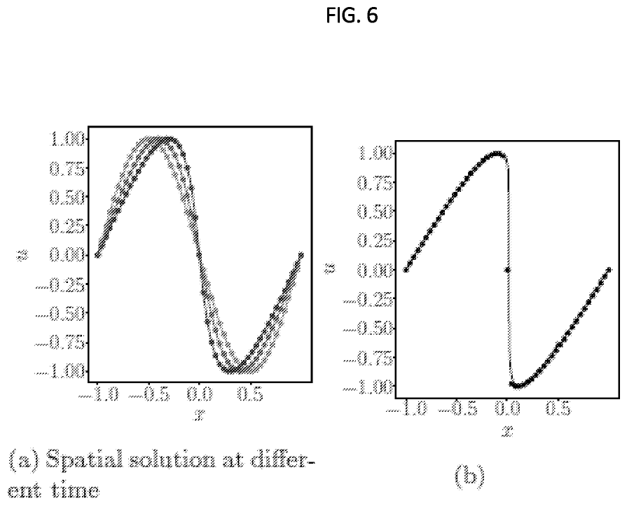

The parameters of the example EDNN used for the Burgers equation is shown in Table 2 (case 1b). The EDNN prediction is compared to the reference solution in FIG. 6 at different stages. At early times (panel a), the gradient of solution is not appreciable and is therefore resolved and accurately predicted by the network. At the late stages in the development of the N-wave (panel b), the solution develops a steep gradient at x=0 and becomes nearly discontinuous. The prediction from EDNN continues to accurately capture the reference solution.

At approximately x=0.4, a small-amplitude oscillation is observed in the solution, which is far from the location of the N-wave discontinuity. The formation of such oscillation can be due to non-linear evolution of a small wiggle in the representation of the initial condition. Absent any viscous dissipation, as demonstrated by the linear wave equation, such initial oscillation can form a local N-wave at long time.

FIG. 6 shows an example of a numerical solution of N-wave formation using EDNN. Panel (a) shows the solution at t=0.0, 0.1, 0.2. Panel (b) shows the solution at t=0.4. In each panel, the data points represent the true solution, and the solid line represents the EDNN solution.

### 3.3. Kuramoto-Sivashinsky Equation

In this example, the Kuramoto-Sivashinsky (KS) equation is solved using EDNN. The nonlinear 4^{th} order PDE is well known for its bifurcations and chaotic dynamics, and has been subject of extensive numerical study [11, 22, 20]. The ability of EDNN to predict bifurcations of the solution is investigated, and a discussion presented of chaotic solutions to simulations of the Kolmogorov flow and its long-time statistics (§ 3.4.2). The following form of the KS equations is considered,

$$\frac{\partial u}{\partial t} + u \frac{\partial u}{\partial x} + \frac{{\partial }^{2} u}{\partial {x}^{2}} + \frac{{\partial }^{4} u}{\partial {x}^{4}} = 0 , \qquad ( 33 )$$

with periodic boundary conditions at the two end points of the domain, and the initial condition,

$$u ( x , t = 0 ) = sin ( \frac{x}{10} ) , x ∈ [ - 10 , 10 ] . \qquad ( 34 )$$

The parameters for solving the numerical solution of Kuramoto-Sivashinsky equation (33) using EDNN are provided in Table (3). All three cases adopt the same EDNN architecture, with four layers (L=4) each with twenty neurons n_{L}=20. The spatial domain is represented by Nₓ=1000 uniformly distributed points, although no restriction is imposed on the sampling of the points over the spatial domain which could have been, for example, randomly uniformly distributed. Cases 1k and 2k adopt the same time-step Δt, and are intended to contrast the accuracy of forward Euler (FE) and Runge-Kutta (RK) time marching schemes for updating the network parameters. Case 3k also uses RK but with a finer time-step.

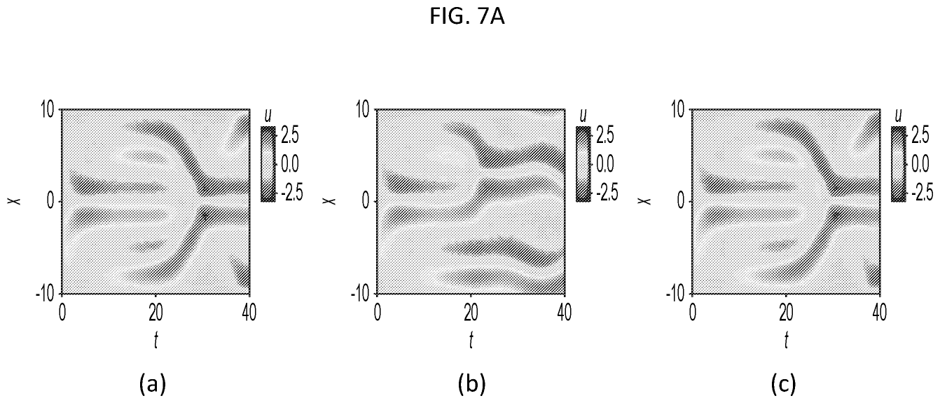

FIG. 7 shows, in panel (a), the behavior of a reference solution evaluated using a spectral Fourier discretization in space and exponential time differencing 4^{th} order Runge-Kutta method [12] with Δt=10⁻³. Panels (b) and (c) show the predictions from cases 2k and 3k using EDNN. The solution of case 2k diverges from the reference spectral solution for two reasons. Firstly, the time step size Δt in case 2k is large compared to the spectral solution, which introduces large discretization errors in the time stepping. In case 3k, the step size Δt is reduced to 10⁻³ and the prediction by EDNN shows good agreement with the reference spectral solution. Secondly, the trajectory predicted by solving the KS equation is very sensitive to its initial condition. That initial state is prescribed by training to set the initial state of EDNN, and therefore the initial condition is enforced with finite precision, in this case O(10⁻³) relative error. The initial error is then propagated and magnified through the trajectory of the solution, as in any chaotic dynamical system.

The errors between the reference spectral solution and the three cases listed in Table 3 are evaluated,

$$ε = \frac{{‖ \hat{u} ( t ) - u ( t ) ‖}_{2}}{{‖ u ( 0 ) ‖}_{2}} , \qquad ( 35 )$$

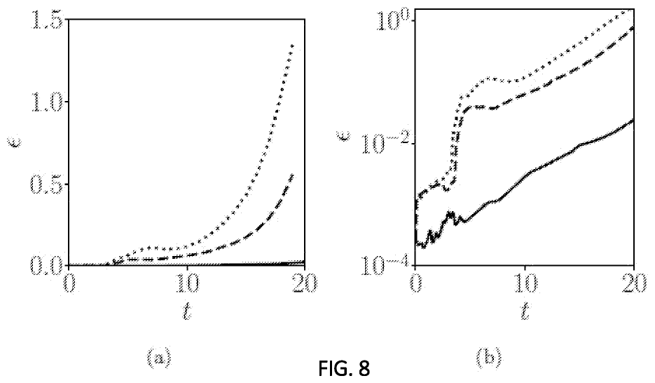

and shown in FIG. 8, both in linear and logarithmic scales. The Euler time advancement of the Network parameters shows the earliest amplification of errors, or divergence of the trajectories predicted by EDNN and the reference spectral solution. At the same time-step size, the RK time marching has lower error and reducing its time-step size even further delays the amplification of ϵ. Despite this trend, since the equations are chaotic, even infinitesimally close trajectories will ultimately diverge in forward time at an exponential Lyapunov rate. Therefore, when plotted in logarithmic scale, the errors all ultimately have the same slope, but the curves are shifted to lower levels for RK time marching and smaller time step.

FIG. 7 shows an example of a numerical solution of a one-dimensional Kuramoto Sivashinsky equation using EDNN. Panel (a) shows a numerical solution from spectral discretization. Panel (b) shows case 2k, and panel (c) shows case 3k.

FIG. 8 shows an example of error evolution of a KS solution from EDNN against a Fourier spectral solution. The dotted line represents case 1k, the dashed line represents case 2k, and the solid line represents case 3k. Panel (a) shows the error ϵ in linear scale, and panel (b) shows the error ϵ in log scale.

TABLE 3

| | | | | | | time |
|---|---|---|---|---|---|---|
| Case | L | n_{L} | Nₓ | ∈₀ | Δt | discretization |
| 1k | 4 | 20 | 1000 | 3.8 × 10⁻⁴ | 1 × 10⁻² | FE |
| 2k | | | | | 1 × 10⁻² | RK |
| 3k | | | | | 1 × 10⁻³ | RK |

### 3.4. Incompressible Navier-Stokes Equations

In this example, the evolution of the two-dimensional Taylor-Green vortices and of Kolmogorov flow is simulated using EDNN. Both cases are governed by the incompressible Navier-Stokes equations,

$$∇ \cdot u = 0 , \qquad ( 36 )$$

$$\frac{\partial u}{\partial t} + u \cdot ∇ u = - ∇ P + v {∇}^{2} u + f ,$$

where u and P represent the velocity and pressure fields, and f represents a body force. An alternative form of the equations [25, 24],

$$\frac{\partial u}{\partial t} = 𝒫 [ - u \cdot ∇ u ++ v {∇}^{2} u + f ] , \qquad ( 37 )$$

replaces the explicit dependence on pressure by introducing [symbol] which is an abstract projection operator from H¹(Ω) to its subspace H¹(Ω)_{div}. In some embodiments, this form (37) of the Navier-Stokes equation can be solved directly using EDNN, where the projection operator [symbol] is automatically realized by maintaining a divergence-free solution throughout the time evolution.

The minimization problem (3) corresponding to the Navier-Stokes equations (37) is,

$${𝒥}_{P} ( γ ) = \frac{1}{2} {\int }_{Ω} {‖ \frac{\partial \hat{u}}{\partial 𝒲} γ - P [ - \hat{u} \cdot ∇ \hat{u} + v {∇}^{2} \hat{u} + f ] ‖}_{2}^{2} dx . \qquad ( 38 )$$

When the methodology from § (2.2.3) is adopted to constrain û to the solenoidal space, the above cost function can be re-written without the project operator,

$$𝒥 ( γ ) = \frac{1}{2} {\int }_{Ω} {‖ \frac{\partial \hat{u}}{\partial 𝒲} γ - [ - \hat{u} \cdot ∇ \hat{u} + v {∇}^{2} \hat{u} + f ] ‖}_{2}^{2} dx , \qquad ( 39 )$$

The implementation and minimization of (39) does not requires any special treatment, and the projection, which is performed explicitly in fractional step methods, can be automatically realized in EDNN by the least square solution of the linear system (5) associated with (39). The equivalence between (38) and (39) can be formally verified,

$${∇}_{γ} 𝒥 = ( {\int }_{Ω} \frac{\partial {\hat{u}}^{T}}{\partial 𝒲} \frac{\partial \hat{u}}{\partial 𝒲} d x ) {γ}_{o p t} - ( {\int }_{Ω} \frac{\partial \hat{u}}{\partial 𝒲} {𝒩}_{N S} ( \hat{u} ) dx ) = ( {\int }_{Ω} \frac{\partial {\hat{u}}^{T}}{\partial 𝒲} \frac{\partial \hat{u}}{\partial 𝒲} d x ) {γ}_{o p t} - ( {\int }_{Ω} {( 𝒫 \frac{\partial \hat{u}}{\partial 𝒲} )}^{T} {𝒩}_{N S} ( \hat{u} ) dx ) = ( {\int }_{Ω} \frac{\partial {\hat{u}}^{T}}{\partial 𝒲} \frac{\partial \hat{u}}{\partial 𝒲} d x ) {γ}_{o p t} - ( {\int }_{Ω} \frac{\partial {\hat{u}}^{T}}{\partial 𝒲} {𝒫}^{T} {𝒩}_{N S} ( \hat{u} ) dx ) = ( {\int }_{Ω} \frac{\partial {\hat{u}}^{T}}{\partial 𝒲} \frac{\partial \hat{u}}{\partial 𝒲} d x ) {γ}_{o p t} - ( {\int }_{Ω} \frac{\partial {\hat{u}}^{T}}{\partial 𝒲} {𝒫𝒩}_{N S} ( \hat{u} ) dx ) = {∇}_{γ} {𝒥}_{P} ,$$

where [symbol] _{NS}=−û·∇û+v∇²û+f is the RHS of Navier-Stokes equation (37) without the projection operator [symbol] . The second equality above holds because the columns of ∂û/∂ [symbol] are all divergence-free, and the fourth equality uses the fact that [symbol] is an orthogonal projection operator. This validity an accuracy of this approach can also be demonstrated empirically through comparison of EDNN and analytical solutions of the incompressible Navier-Stokes equation.

### 3.4.1. Taylor-Green Vortex

Two-dimensional Taylor-Green vortices are an exact time-dependent solution of the Navier-Stokes equations. This flow has been adopted extensively as a benchmark to demonstrate accuracy of various algorithms. The initial condition is,

$$u ( x , y , t = 0 ) = {U}_{0} cos ( \frac{x}{{L}_{x}} ) sin ( \frac{y}{{L}_{y}} ) , \qquad ( 41 )$$

$$v ( x , y , t = 0 ) = - {U}_{0} sin ( \frac{x}{{L}_{x}} ) cos ( \frac{y}{{L}_{y}} ) ,$$

and in absence of external forcing (f=0) the time-dependent velocity field is,

$$u ( x , y , t = 0 ) = {U}_{0} cos ( \frac{x}{{L}_{x}} ) sin ( \frac{y}{{L}_{y}} ) {e}^{- 2 v t} , \qquad ( 42 )$$

$$v ( x , y , t = 0 ) = - {U}_{0} sin ( \frac{x}{{L}_{x}} ) cos ( \frac{y}{{L}_{y}} ) {e}^{- 2 v t} ,$$

where Lₓ=L_{y}=2π are the dimensions of the flow domain. Periodicity is enforced on the boundaries of the domain.

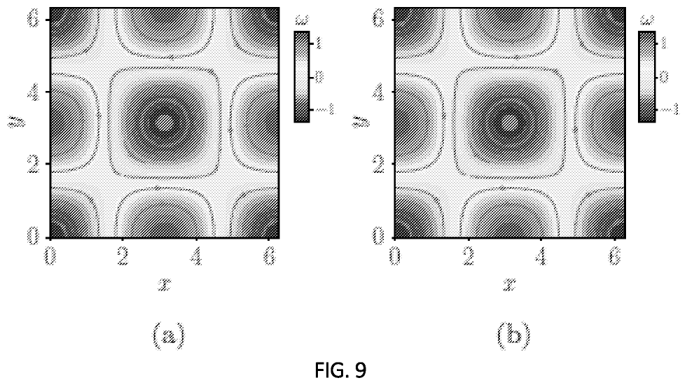

A comparison of the analytical and EDNN solutions is provided in FIG. 9. The contours show the vorticity field ω=∇×u and lines mark streamlines that are tangent to the velocity field. The prediction by EDNN shows excellent agreement with the analytical solution at t=0.2, and satisfies the periodic boundary condition.

In order to quantify the accuracy of EDNN predictions, a series of nine test cases, denoted 1t through 9t, were performed and are listed in Table 4. All EDNN architectures are comprised of L=4 layers, and three network sizes were achieved by increasing the number of neurons per layer n_{L}={10, 20, 30}. The three values of n_{L} were adopted for three resolutions of the solution points (Nₓ, N_{y}) in the two-dimensional domain, and at each spatial resolution a number of time-steps Δt were examined.

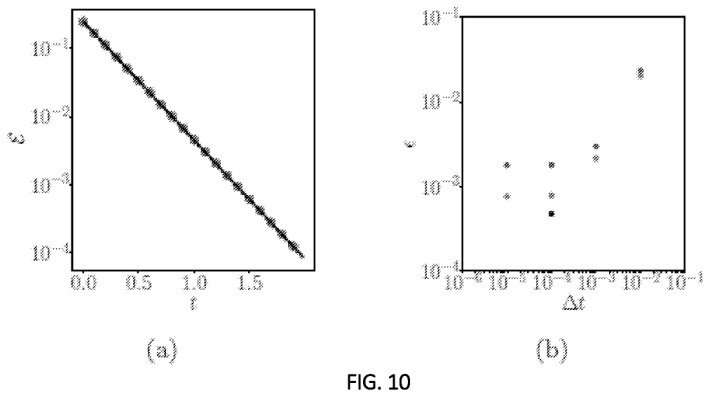

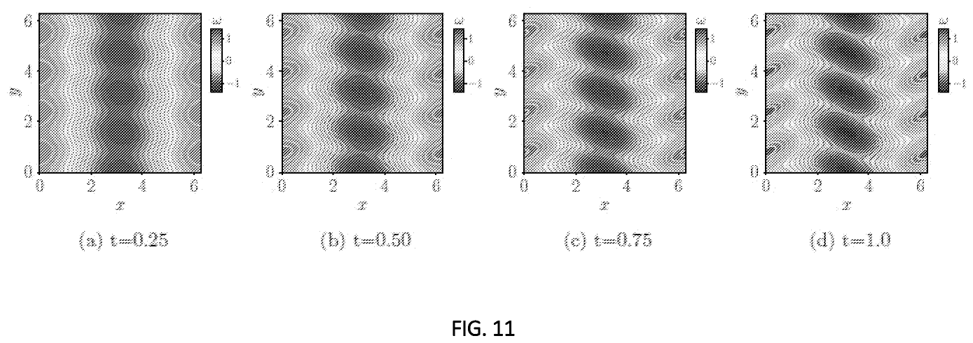

Quantitative assessment of the accuracy of EDNN is provided in FIG. 10. First, the decay of the domain-averaged energy of the vortex ε=(1/|Ω|)∫_{Ω}u²dΩ is plotted in panel (a) for all nine cases which all compare favorably to the analytical solution. The time-averaged root-mean-squared errors in the solution,

$$ϵ = \frac{1}{T} {\int }_{0}^{T} \frac{{‖ u ( t ) - \hat{u} ( t ) ‖}_{2}}{{‖ u ( t ) ‖}_{2}} dt , \qquad ( 43 )$$

are plotted in panel (b). For any of the time-steps considered, as the number of solution points (Nₓ, N_{y}) is increased, and with it the number of neurons per layer n_{L}, the errors in the EDNN prediction is reduced. In addition, as the time-step is reduced from Δt=10⁻² to 10⁻⁴, the errors monotonically decrease. Below Δt=10⁻⁴, the error saturates which is in part due to errors in the representation of the initial condition and from spatial discretization using the neural network. The solution satisfies the divergence-free condition to machine precision, which is anticipated because of the constraint was embedded in the EDNN design and derivatives are computed using automatic differentiation.

FIG. 9 shows an example comparison of an analytical solution and an EDNN solution of the Taylor Green vortex at t=0.2. The color shows the value of vorticity. The lines with arrows are streamlines. Panel (a) shows the analytical solution. Panel (b) shows case 6t using EDNN.

FIG. 10 shows an example of a quantitative evaluation of the EDNN solution of the Taylor Green vortex. Panel (a) shows an energy decaying rate of the EDNN solution against analytical prediction. Panel (b) shows the relative error on the solution with respect to Δt.

TABLE 4

| Case | L | n_{L} | Nₓ | N_{y} | Δt |
|---|---|---|---|---|---|
| 1t | 4 | 10 | 33 | 33 | 1 × 10⁻² |
| 2t | | | | | 1 × 10⁻³ |
| 3t | | | | | 1 × 10⁻⁴ |
| 4t | | | | | 1 × 10⁻⁵ |
| 5t | | 20 | 65 | 65 | 1 × 10⁻² |
| 6t | | | | | 1 × 10⁻³ |
| 7t | | | | | 1 × 10⁻⁴ |
| 8t | | | | | 1 × 10⁻⁵ |
| 9t | | 30 | 129 | 129 | 1 × 10⁻⁴ |

### 3.4.2. Kolmogorov Flow

The final Navier-Stokes example that is considered is the Kolmogorov flow, which is a low dimensional chaotic dynamical system that exhibits complex behaviors including instability, bifurcation, periodic orbits and turbulence [4, 17]. The accurate simulation of long time chaotic dynamical system is important and also a challenge to the algorithm, thus it is chosen as a numerical example.

The objective of this example will be to demonstrate that in some embodiments, EDNN can accurately predict trajectories of this flow in state space when starting from a laminar initial condition, and also long-time statistics when the initial condition is within the statistically stationary chaotic regime. The latter objective is extremely challenging because very long-time integration is required for convergence of statistics, and is therefore not possible to achieve using conventional PINNs but will be demonstrated here using an embodiment of EDNN.

The incompressible NS equation equations (36) are solved with forcing in the horizontal x direction, f=χsin (ny)eₓ, where χ=0.1 is the forcing amplitude and n is the vertical wavenumber. Simulations starting from a laminar condition adopted the initial field,

u(x,y,t=0)=0,

v(x,y,t=0)=−sin (x). (44)

The spatial domain of the Kolmogorov flow is fixed on [−π, π]². The Reynolds number is defined as Re=\sqrt{χ}/v consistent with [4]. Independent simulations were performed using Fourier spectral discretization of the Navier-Stokes equations (see Table 5), at high spectral resolution and with a small time-step, because these are intended as reference solutions. Two forcing wavenumbers were considered: Case 1kfS with n=4 generates a laminar flow trajectory starting from equation (44); Case 2kfs with n=2 adds random noise to the initial field (44) in order to promote transition to a chaotic turbulent state, and flow statistics are evaluated once statistical stationarity is achieved.

Parameters for Kolmogorov flow simulations using Fourier spectral methods and EDNN are also listed in Table 5, all using the same network architecture, number of spatial points and time-step. The laminar case (1kfE, n=4) shares the same initial condition (44) as the spectral solution; The turbulent case (2kfE, n=2), on the other hand, was simulated starting from a statistically stationary state extracted from the spectral computation, and therefore statistics were evaluated immediately from the initial time.

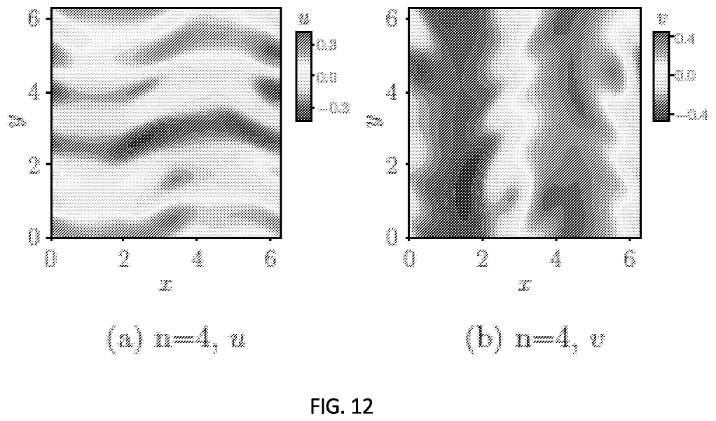

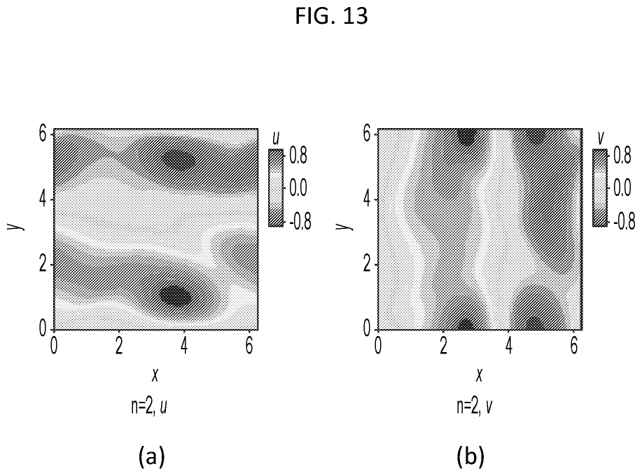

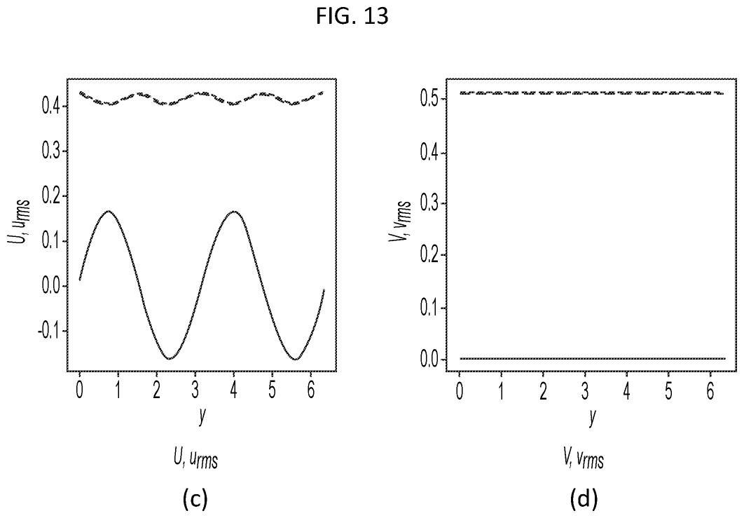

The laminar cases 1kfs and 1kfE are compared in FIG. 11. Contours of the vorticity field ω=∇×u are plotted using color for the EDNN solution and lines for the spectral reference case, and their agreement demonstrates the accuracy of EDNN in predicting the time evolution. If noise is added to the initial condition, these cases transition to turbulence. A snapshot of such turbulent velocity field obtained using EDNN at very long time, t=10⁴, is shown in FIG. 12 to confirm that transition to turbulence can indeed be achieved. It is well known, however, that convergence of first and second order statistics when n=4 is extremely challenging, and requires sampling over a duration on the order of at least 10⁶ time units [17]. Therefore, n=2 was adopted for the computation of turbulent flow statistics, where convergence is achieved faster, but nonetheless still requiring long challenging integration times. A realization of the statistically stationary state from EDNN (case 2kfE) is shown in FIG. 13. The velocity field shows evidence of the forcing wavenumber, but is clearly irregular. Long-time flow statistics from both EDNN and the spectral simulation (2kfs) also shown in the figure. The black curves are the mean velocity and blue ones show the root-mean-squared perturbations as a function of the vertical coordinate. The agreement of the EDNN prediction with the reference spectral solution is notable, even though the spatio-temporal resolution in EDNN is coarser. It is also noted that these simulations were performed over a very long times (6×10⁵ for spectral and 4×10⁵ for EDNN). Performing such long-time evolutions of turbulent trajectories has never been demonstrated with PINNs due to the prohibitive computational cost, and was here demonstrated to be accurately achieved with EDNN.

TABLE 5

| | Case | L | n_{L} | Nₓ | N_{y} | Δt | Re | n | I.C. |
|---|---|---|---|---|---|---|---|---|---|
| Spectral | 1kfS | | | 128 | 128 | 1 × 10⁻³ | 33 | 4 | L |
| | 2kfS | | | | | | | 2 | T |
| EDNN | 1kfE | 4 | 20 | 65 | 65 | 1 × 10⁻² | 33 | 4 | L |
| | 2kfE | | | | | | | 2 | T |

FIG. 11 shows an example of an instantaneous comparison of vorticity ω from Kolmogorov flow between a spectral method and EDNN. The color are from case 1kfE, and the contour lines are from 1kfS.

FIG. 12 shows an example of fully developed turbulent snapshots of velocity components from EDNN calculations with n=4 at t=10⁵.

FIG. 13 shows fully-developed turbulent snapshots and long-time statistics of chaotic Kolmogorov flow from spectral methods (case 2kfS) and EDNN (case 2kfE) with n=2. Panels (a) and (b) are flow snapshots at t=10⁵ In panels (c) and (d), the solid lines are statistics from spectral methods (case 2kfS), and the dashed lines are from EDNN calculations (2kfE). The black color and blue color represent mean velocity and root mean square velocity respectively on both directions.

### 4. Conclusions

A new framework is introduced for simulating the evolution of solutions to partial differential equations using neural network. Spatial dimensions are discretized using the neural network, and automatic differentiation is used to compute spatial derivatives. The temporal evolution is expressed in terms of an evolution equation for the network parameters, or weights, which are updated using a marching scheme. Starting from the initial network state that represents the initial condition, the weights of the Evolutional Deep Neural Network (EDNN) are marched to predict the solution trajectory of the PDE over any time horizon of interest. Boundary conditions and other linear constraints on the solution of the PDE are enforced on the neural network by the introduction of auxiliary functions and auxiliary operators. The EDNN methodology is flexible, and can be easily adapted to other types of PDE problems. For example, in boundary-layer flows, the governing equations are often marched in the parabolic streamwise direction [5, 6, 21]. In this case, the inputs to EDNN would be the spatial coordinates in the cross-flow plane, and the network weights would be marched in the streamwise direction instead of time.

Several PDE problems were solved using EDNN in order to demonstrate its versatility and accuracy, including two-dimensional heat equation, linear wave equation and Burgers equation. Tests with the Kuramoto-Sivashinsky equation focused on the ability of EDNN to accurately predict bifurcations. For the two-dimensional incompressible Navier-Stokes equations, an approach is introduced where the projection step which ensures solenoidal velocity fields is automatically realized by an embedded divergence-free constraints. Decaying Taylor-Green vortices are then simulated. In all cases, the solutions from EDNN show good agreement with either analytical solutions or reference spectral discretizations. In addition, the accuracy of EDNN monotonically improves with the refinement of neural network structure, and the adopted spatio-temporal resolution for representing the solution. For Navier-Stokes equations, the evolution of Kolmogorov flow in the early laminar regime was also considered, as well as its long-time statistics in the chaotic turbulent regime. Again, the predictions of EDNN were accurate, and its ability to simulate long time horizons was highlighted.

EDNN has several noteworthy characteristics. Previous neural network methods for time dependent PDE, for example PINNs, perform an optimization on the whole spatio-temporal domain. In contrast, the state of EDNN only represents an instantaneous snapshot of the PDE solution. Thus, the structural complexity of EDNN can be significantly smaller than PINN for a specific PDE problem. Secondly, the EDNN maintains deterministic time dependency and causality, while most of other methods only try to minimize the penalty on equation residuals. Thirdly, EDNN can simulate very long-time evolutions of chaotic solutions of the PDE, which is difficult to achieve in other NN based methods.

The neural network of some embodiments is an example of a multi-layer machine-trained network (e.g., a feed-forward neural network). Neural networks, also referred to as machine-trained networks, will be herein described. One class of machine-trained networks are deep neural networks with multiple layers of nodes. Different types of such networks include feed-forward networks, convolutional networks, recurrent networks, regulatory feedback networks, radial basis function networks, long-short term memory (LSTM) networks, and Neural Turing Machines (NTM). Multi-layer networks are trained to execute a specific purpose, including face recognition or other image analysis, voice recognition or other audio analysis, large-scale data analysis (e.g., for climate data), etc. In some embodiments, such a multi-layer network is designed to execute on a mobile device (e.g., a smartphone or tablet), an IOT device, a web browser window, etc.

A typical neural network operates in layers, each layer having multiple nodes. In convolutional neural networks (a type of feed-forward network), a majority of the layers include computation nodes with a (typically) nonlinear activation function, applied to the dot product of the input values (either the initial inputs based on the input data for the first layer, or outputs of the previous layer for subsequent layers) and predetermined (i.e., trained) weight values, along with bias (addition) and scale (multiplication) terms, which may also be predetermined based on training. Other types of neural network computation nodes and/or layers do not use dot products, such as pooling layers that are used to reduce the dimensions of the data for computational efficiency and speed.

For convolutional neural networks that are often used to process electronic image and/or video data, the input activation values for each layer (or at least each convolutional layer) are conceptually represented as a three-dimensional array. This three-dimensional array is structured as numerous two-dimensional grids. For instance, the initial input for an image is a set of three two-dimensional pixel grids (e.g., a 1280×720 RGB image will have three 1280×720 input grids, one for each of the red, green, and blue channels). The number of input grids for each subsequent layer after the input layer is determined by the number of subsets of weights, called filters, used in the previous layer (assuming standard convolutional layers). The size of the grids for the subsequent layer depends on the number of computation nodes in the previous layer, which is based on the size of the filters, and how those filters are convolved over the previous layer input activations. For a typical convolutional layer, each filter is a small kernel of weights (often 3×3 or 5×5) with a depth equal to the number of grids of the layer's input activations. The dot product for each computation node of the layer multiplies the weights of a filter by a subset of the coordinates of the input activation values. For example, the input activations for a 3×3×Z filter are the activation values located at the same 3×3 square of all Z input activation grids for a layer.

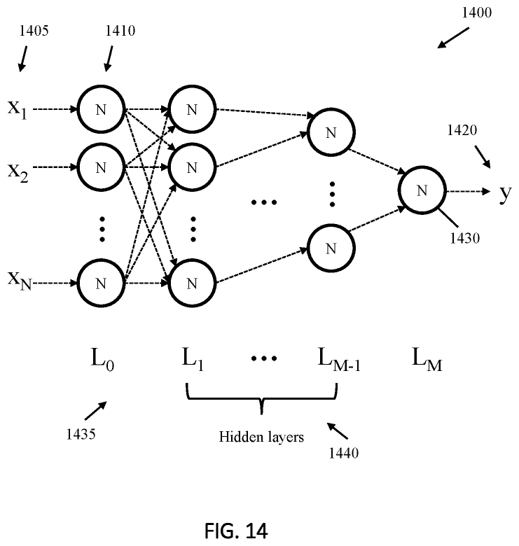

FIG. 14 illustrates an example of a multi-layer machine-trained network used as an EDNN in some embodiments. This figure illustrates a feed-forward neural network 1400 that receives an input vector 1405 (denoted x₁, x₂, . . . x_{N}) at multiple input nodes 1410 and computes an output 1420 (denoted by y) at an output node 1430. The neural network 1400 has multiple layers L₀, L₁, L₂ . . . L_{M} 1435 of processing nodes (also called neurons, each denoted by N). In all but the first layer (input, L₀) and last layer (output, L_{M}), each node receives two or more outputs of nodes from earlier processing node layers and provides its output to one or more nodes in subsequent layers. These layers are also referred to as the hidden layers 1440. Though only a few nodes are shown in FIG. 14 per layer, a typical neural network may include a large number of nodes per layer (e.g., several hundred or several thousand nodes) and significantly more layers than shown (e.g., several dozen layers). The output node 1430 in the last layer computes the output 1420 of the neural network 1400.

In this example, the neural network 1400 only has one output node 1430 that provides a single output 1420. Other neural networks of other embodiments have multiple output nodes in the output layer L_{M} that provide more than one output value. In different embodiments, the output 1420 of the network is a scalar in a range of values (e.g., 0 to 1), a vector representing a point in an N-dimensional space (e.g., a 128-dimensional vector), or a value representing one of a predefined set of categories (e.g., for a network that classifies each input into one of eight possible outputs, the output could be a three-bit value).

Portions of the illustrated neural network 1400 are fully-connected in which each node in a particular layer receives as inputs all of the outputs from the previous layer. For example, all the outputs of layer L₀ are shown to be an input to every node in layer L₁. The neural networks of some embodiments are convolutional feed-forward neural networks, where the intermediate layers (referred to as “hidden” layers) may include other types of layers than fully-connected layers, including convolutional layers, pooling layers, and normalization layers.

The convolutional layers of some embodiments use a small kernel (e.g., 3×3×3) to process each tile of pixels in an image with the same set of parameters. The kernels (also referred to as filters) are three-dimensional, and multiple kernels are used to process each group of input values in a layer (resulting in a three-dimensional output). Pooling layers combine the outputs of clusters of nodes from one layer into a single node at the next layer, as part of the process of reducing an image (which may have a large number of pixels) or other input item down to a single output (e.g., a vector output). In some embodiments, pooling layers can use max pooling (in which the maximum value among the clusters of node outputs is selected) or average pooling (in which the clusters of node outputs are averaged).

Each node computes a dot product of a vector of weight coefficients and a vector of output values of prior nodes (or the inputs, if the node is in the input layer), plus an offset. In other words, a hidden or output node computes a weighted sum of its inputs (which are outputs of the previous layer of nodes) plus an offset (also referred to as a bias). Each node then computes an output value using a function, with the weighted sum as the input to that function. This function is commonly referred to as the activation function, and the outputs of the node (which are then used as inputs to the next layer of nodes) are referred to as activations.

Consider a neural network with one or more hidden layers 1440 (i.e., layers that are not the input layer or the output layer). The index variable l can be any of the hidden layers of the network (i.e., l∈{1, . . . , M−1}, with l=0 representing the input layer and l=M representing the output layer).

The output yₗ₊₁ of node in hidden layer l+1 can be expressed as:

yₗ₊₁=ƒ((wₗ₊₁·yₗ)*c+bₗ₊₁) (44)

This equation describes a function, whose input is the dot product of a vector of weight values wₗ₊₁ and a vector of outputs yₗ from layer l, which is then multiplied by a constant value c, and offset by a bias value bₗ₊₁. The constant value c is a value to which all the weight values are normalized. In some embodiments, the constant value c is 1. The symbol * is an element-wise product, while the symbol is the dot product. The weight coefficients and bias are parameters that are adjusted during the network's training in order to configure the network to solve a particular problem (e.g., object or face recognition in images, voice analysis in audio, depth analysis in images, etc.).

In equation (44), the function ƒ is the activation function for the node. Examples of such activation functions include a sigmoid function (ƒ(x)=1/(1+e^{-x})), a tanh function, or a ReLU (rectified linear unit) function (ƒ(x)=max (0, x)). See Nair, Vinod and Hinton, Geoffrey E., “Rectified linear units improve restricted Boltzmann machines,” ICML, pp. 807-814, 2010, incorporated herein by reference in its entirety. In addition, the “leaky” ReLU function (ƒ(x)=max (0.01*x, x)) has also been proposed, which replaces the flat section (i.e., x<0) of the ReLU function with a section that has a slight slope, usually 0.01, though the actual slope is trainable in some embodiments. See He, Kaiming, Zhang, Xiangyu, Ren, Shaoqing, and Sun, Jian, “Delving deep into rectifiers: Surpassing human-level performance on imagenet classification,” arXiv preprint arXiv:1502.01852, 2015, incorporated herein by reference in its entirety. In some embodiments, the activation functions can be other types of functions, including gaussian functions and periodic functions.

Before a multi-layer network can be used to solve a particular problem, the network is put through a supervised training process that adjusts the network's configurable parameters (e.g., the weight coefficients, and additionally in some cases the bias factor). The training process iteratively selects different input value sets with known output value sets. For each selected input value set, the training process typically (1) forward propagates the input value set through the network's nodes to produce a computed output value set and then (2) back-propagates a gradient (rate of change) of a loss function (output error) that quantifies the difference between the input set's known output value set and the input set's computed output value set, in order to adjust the network's configurable parameters (e.g., the weight values).

In some embodiments, training the neural network involves defining a loss function (also called a cost function) for the network that measures the error (i.e., loss) of the actual output of the network for a particular input compared to a pre-defined expected (or ground truth) output for that particular input. During one training iteration (also referred to as a training epoch), a training dataset is first forward-propagated through the network nodes to compute the actual network output for each input in the data set. Then, the loss function is back-propagated through the network to adjust the weight values in order to minimize the error (e.g., using first-order partial derivatives of the loss function with respect to the weights and biases, referred to as the gradients of the loss function). The accuracy of these trained values is then tested using a validation dataset (which is distinct from the training dataset) that is forward propagated through the modified network, to see how well the training performed. If the trained network does not perform well (e.g., have error less than a predetermined threshold), then the network is trained again using the training dataset. This cyclical optimization method for minimizing the output loss function, iteratively repeated over multiple epochs, is referred to as stochastic gradient descent (SGD).

In some embodiments the neural network is a deep aggregation network, which is a stateless network that uses spatial residual connections to propagate information across different spatial feature scales. Information from different feature scales can branch-off and re-merge into the network in sophisticated patterns, so that computational capacity is better balanced across different feature scales. Also, the network can learn an aggregation function to merge (or bypass) the information instead of using a non-learnable (or sometimes a shallow learnable) operation found in current networks.

Deep aggregation networks include aggregation nodes, which in some embodiments are groups of trainable layers that combine information from different feature maps and pass it forward through the network, skipping over backbone nodes. Aggregation node designs include, but are not limited to, channel-wise concatenation followed by convolution (e.g., DispNet), and element-wise addition followed by convolution (e.g., ResNet). See Mayer, Nikolaus, Ilg, Eddy, Häusser, Philip, Fischer, Philipp, Cremers, Daniel, Dosovitskiy, Alexey, and Brox, Thomas, “A Large Dataset to Train Convolutional Networks for Disparity, Optical Flow, and Scene Flow Estimation,” arXiv preprint arXiv:1512.02134, 2015, incorporated herein by reference in its entirety. See He, Kaiming, Zhang, Xiangyu, Ren, Shaoqing, and Sun, Jian, “Deep Residual Learning for Image Recognition,” arXiv preprint arXiv: 1512.03385, 2015, incorporated herein by reference in its entirety.

As used in this specification, the terms “computer”, “server”, “processor”, and “memory” all refer to electronic or other technological devices. These terms exclude people or groups of people. As used in this specification, the terms “computer readable medium,” “computer readable media,” and “machine readable medium,” etc. are entirely restricted to tangible, physical objects that store information in a form that is readable by a computer. These terms exclude any wireless signals, wired download signals, and any other ephemeral signals.

The term “computer” is intended to have a broad meaning that may be used in computing devices such as, e.g., but not limited to, standalone or client or server devices. The computer may be, e.g., (but not limited to) a personal computer (PC) system running an operating system such as, e.g., (but not limited to) MICROSOFT® WINDOWS® available from MICROSOFT® Corporation of Redmond, Wash., U.S.A. or an Apple computer executing MAC® OS from Apple® of Cupertino, Calif, U.S.A. However, the invention is not limited to these platforms. Instead, the invention may be implemented on any appropriate computer system running any appropriate operating system. In one illustrative embodiment, the present invention may be implemented on a computer system operating as discussed herein. The computer system may include, e.g., but is not limited to, a main memory, random access memory (RAM), and a secondary memory, etc. Main memory, random access memory (RAM), and a secondary memory, etc., may be a computer-readable medium that may be configured to store instructions configured to implement one or more embodiments and may comprise a random-access memory (RAM) that may include RAM devices, such as Dynamic RAM (DRAM) devices, flash memory devices, Static RAM (SRAM) devices, etc.

The secondary memory may include, for example, (but not limited to) a hard disk drive and/or a removable storage drive, representing a floppy diskette drive, a magnetic tape drive, an optical disk drive, a read-only compact disk (CD-ROM), digital versatile discs (DVDs), flash memory (e.g., SD cards, mini-SD cards, micro-SD cards, etc.), read-only and recordable Blu-Ray® discs, etc. The removable storage drive may, e.g., but is not limited to, read from and/or write to a removable storage unit in a well-known manner. The removable storage unit, also called a program storage device or a computer program product, may represent, e.g., but is not limited to, a floppy disk, magnetic tape, optical disk, compact disk, etc. which may be read from and written to the removable storage drive. As will be appreciated, the removable storage unit may include a computer usable storage medium having stored therein computer software and/or data.

In alternative illustrative embodiments, the secondary memory may include other similar devices for allowing computer programs or other instructions to be loaded into the computer system. Such devices may include, for example, a removable storage unit and an interface. Examples of such may include a program cartridge and cartridge interface (such as, e.g., but not limited to, those found in video game devices), a removable memory chip (such as, e.g., but not limited to, an erasable programmable read only memory (EPROM), or programmable read only memory (PROM) and associated socket, and other removable storage units and interfaces, which may allow software and data to be transferred from the removable storage unit to the computer system.

Some embodiments include electronic components, such as microprocessors, storage and memory that store computer program instructions in a machine-readable or computer-readable medium (alternatively referred to as computer-readable storage media, machine-readable media, or machine-readable storage media). The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

The computer may also include an input device may include any mechanism or combination of mechanisms that may permit information to be input into the computer system from, e.g., a user. The input device may include logic configured to receive information for the computer system from, e.g., a user. Examples of the input device may include, e.g., but not limited to, a mouse, pen-based pointing device, or other pointing device such as a digitizer, a touch sensitive display device, and/or a keyboard or other data entry device (none of which are labeled). Other input devices may include, e.g., but not limited to, a biometric input device, a video source, an audio source, a microphone, a web cam, a video camera, and/or another camera. The input device may communicate with a processor either wired or wirelessly.

The computer may also include output devices which may include any mechanism or combination of mechanisms that may output information from a computer system. An output device may include logic configured to output information from the computer system. Embodiments of output device may include, e.g., but not limited to, display, and display interface, including displays, printers, speakers, cathode ray tubes (CRTs), plasma displays, light-emitting diode (LED) displays, liquid crystal displays (LCDs), printers, vacuum florescent displays (VFDs), surface-conduction electron-emitter displays (SEDs), field emission displays (FEDs), etc. The computer may include input/output (I/O) devices such as, e.g., (but not limited to) communications interface, cable and communications path, etc. These devices may include, e.g., but are not limited to, a network interface card, and/or modems. The output device may communicate with processor either wired or wirelessly. A communications interface may allow software and data to be transferred between the computer system and external devices.

The term “data processor” is intended to have a broad meaning that includes one or more processors, such as, e.g., but not limited to, that are connected to a communication infrastructure (e.g., but not limited to, a communications bus, cross-over bar, interconnect, or network, etc.). The term data processor may include any type of processor, microprocessor and/or processing logic that may interpret and execute instructions, including application-specific integrated circuits (ASICs) and field-programmable gate arrays (FPGAs). The data processor may comprise a single device (e.g., for example, a single core) and/or a group of devices (e.g., multi-core). The data processor may include logic configured to execute computer-executable instructions configured to implement one or more embodiments. The instructions may reside in main memory or secondary memory. The data processor may also include multiple independent cores, such as a dual-core processor or a multi-core processor. The data processors may also include one or more graphics processing units (GPU) which may be in the form of a dedicated graphics card, an integrated graphics solution, and/or a hybrid graphics solution. Various illustrative software embodiments may be described in terms of this illustrative computer system. After reading this description, it will become apparent to a person skilled in the relevant art(s) how to implement the invention using other computer systems and/or architectures.

The term “data storage device” is intended to have a broad meaning that includes removable storage drive, a hard disk installed in hard disk drive, flash memories, removable discs, non-removable discs, etc. In addition, it should be noted that various electromagnetic radiation, such as wireless communication, electrical communication carried over an electrically conductive wire (e.g., but not limited to twisted pair, CAT5, etc.) or an optical medium (e.g., but not limited to, optical fiber) and the like may be encoded to carry computer-executable instructions and/or computer data that embodiments of the invention on e.g., a communication network. These computer program products may provide software to the computer system. It should be noted that a computer-readable medium that comprises computer-executable instructions for execution in a processor may be configured to store various embodiments of the present invention.

The term “network” is intended to include any communication network, including a local area network (“LAN”), a wide area network (“WAN”), an Intranet, or a network of networks, such as the Internet.

The term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

### REFERENCES

[1] A. R. Barron. Universal approximation bounds for superpositions of a sigmoidal function. IEEE Transactions on Information theory, 39(3):930-945, 1993.

[2] J. Berg and K. Nyström. A unified deep artificial neural network approach to partial differential equations in complex geometries. Neurocomputing, 317:28-41, 2018.

[3] S. Cai, Z. Wang, L. Lu, T. A. Zaki, and G. E. Karniadakis. DeepM&Mnet: Inferring the electro-convection multiphysics fields based on operator approximation by neural networks. arXiv preprint arXiv:2009.12935, 2020.

[4] G. J. Chandler and R. R. Kerswell. Invariant recurrent solutions embedded in a turbulent two-dimensional Kolmogorov flow. Journal of Fluid Mechanics, 722:554-595, 2013.

[5] L. C. Cheung and T. A. Zaki. Linear and nonlinear instability waves in spatially developing two-phase mixing layers. Physics of Fluids, 22(5):052103, 2010.

[6] L. C. Cheung and T. A. Zaki. A nonlinear pse method for two-fluid shear flows with complex interfacial topology. Journal of Computational Physics, 230(17):6756-6777, 2011.

[7] G. Cybenko. Approximation by superpositions of a sigmoidal function. Mathematics of control, signals and systems, 2(4):303-314, 1989.

[8] M. Dissanayake and N. Phan-Thien. Neural-network-based approximations for solving partial differential equations. communications in Numerical Methods in Engineering, 10(3):195-201, 1994.

[9] K. Hornik. Approximation capabilities of multilayer feedforward networks. Neural networks, 4(2): 251-257, 1991.

[10] K. Hornik, M. Stinchcombe, H. White, et al. Multilayer feedforward networks are universal approximators. Neural networks, 2(5):359-366, 1989.

[11] J. M. Hyman and B. Nicolaenko. The Kuramoto-Sivashinsky equation: a bridge between pde's and dynamical systems. Physica D: Nonlinear Phenomena, 18(1-3):113-126, 1986.

[12] A.-K. Kassam and L. N. Trefethen. Fourth-order time-stepping for stiff pdes. SIAM Journal on Scientific Computing, 26(4):1214-1233, 2005.

[13] I. E. Lagaris, A. Likas, and D. I. Fotiadis. Artificial neural networks for solving ordinary and partial differential equations. IEEE transactions on neural networks, 9(5):987-1000, 1998.

[14] Z. Li, N. Kovachki, K. Azizzadenesheli, B. Liu, K. Bhattacharya, A. Stuart, and A. Anandkumar. Fourier neural operator for parametric partial differential equations. arXiv preprint arXiv:2010.08895, 2020.

[15] J. Lu, Z. Shen, H. Yang, and S. Zhang. Deep network approximation for smooth functions. arXiv preprint arXiv:2001.03040, 2020.

[16] L. Lu, P. Jin, and G. E. Karniadakis. DeepOnet: Learning nonlinear operators for identifying differential equations based on the universal approximation theorem of operators. arXiv preprint arXiv:1910.03193, 2019.

[17] D. Lucas and R. R. Kerswell. Recurrent flow analysis in spatiotemporally chaotic 2-dimensional Kolmogorov flow. Physics of Fluids, 27(4):045106, 2015.

[18] Z. Mao, A. D. Jagtap, and G. E. Karniadakis. Physics-informed neural networks for high-speed flows. Computer Methods in Applied Mechanics and Engineering, 360:112789, 2020.

[19] Z. Mao, L. Lu, O. Marxen, T. A. Zaki, and G. E. Karniadakis. DeepM&Mnet for hypersonics: Predicting the coupled flow and finite-rate chemistry behind a normal shock using neural-network approximation of operators. arXiv preprint arXiv:2011.03349, 2020.

[20] J. Page, M. P. Brenner, and R. R. Kerswell. Revealing the state space of turbulence using machine learning. arXiv preprint arXiv:2008.07515, 2020.

[21] J. Park and T. A. Zaki. Sensitivity of high-speed boundary-layer stability to base-flow distortion. Journal of Fluid Mechanics, 859:476-515, 2019.

[22] J. Pathak, B. Hunt, M. Girvan, Z. Lu, and E. Ott. Model-free prediction of large spatiotemporally chaotic systems from data: A reservoir computing approach. Physical review letters, 120(2):024102, 2018.

[23] M. Raissi, P. Perdikaris, and G. E. Karniadakis. Physics-informed neural networks: A deep learning framework for solving forward and inverse problems involving nonlinear partial differential equations. Journal of Computational Physics, 378:686-707, 2019.

[24] R. Temam. Remark on the pressure boundary condition for the projection method. Theoretical and Computational Fluid Dynamics, 3(3):181-184, 1991.

[25] R. Temam. Navier-Stokes equations: theory and numerical analysis, volume 343. American Mathematical Soc., 2001.

[26] S. Wang, Y. Teng, and P. Perdikaris. Understanding and mitigating gradient pathologies in physics-informed neural networks. arXiv preprint arXiv:2001.04536, 2020.

[27] E. Weinan and B. Yu. The deep Ritz method: a deep learning-based numerical algorithm for solving variational problems. Communications in Mathematics and Statistics, 6(1):1-12, 2018.

[28] D. Yarotsky. Optimal approximation of continuous functions by very deep ReLU networks. arXiv preprint arXiv:1802.03620, 2018.

[29] A. Yazdani, L. Lu, M. Raissi, and G. E. Karniadakis. Systems biology informed deep learning for inferring parameters and hidden dynamics. PLOS Computational Biology, 16(11):e1007575, 2020.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described. For example, it is to be understood that the present disclosure contemplates that, to the extent possible, one or more features of any embodiment can be combined with one or more features of any other embodiment.

1. A method of predicting a state of a system that is represented by a partial differential equation, said partial differential equation being a partial differential with respect to time, comprising:
training a neural network for an initial state of said system to obtain a set of neural network parameters to provide a spatial representation of said system at an initial time;
modifying said set of neural network parameters for each of a plurality of intermediate times between said initial time and a prediction time such that each modified set of neural network parameters is used to replace an immediately prior set of neural network parameters in said neural network to provide a respective spatial representation of said system at each corresponding intermediate time using said neural network; and
modifying said set of neural network parameters for said prediction time to provide a prediction set of neural network parameters that is used to replace an immediately prior set of neural network parameters in said neural network to provide a predicted spatial representation of said system at said prediction time using said neural network,
wherein each of said modifying said set of neural network parameters for each intermediate time and for said prediction time is based on a time-dependent property of said partial differential equation without further training of said neural network, and
wherein said state of said system corresponds to said predicted spatial representation of said system at said prediction time.

2. The method according to claim 1, wherein each neural network parameter of each set of neural network parameters is equal to a corresponding neural network parameter of the immediately prior set of neural network parameters plus a respective perturbation value determined from said partial differential equation.

3. The method according to claim 2, wherein each said respective perturbation value is linear in a time difference with respect to said immediately prior set of neural network parameters.

4. A method of solving a nonlinear partial differential equation, comprising:
providing a nonlinear partial differential equation that is a function of n variables, said nonlinear partial differential equation being a partial differential with respect to one of said n variables such that said one of said n variables is an evolution variable;
training a neural network with respect to n-1 of said n variables for an initial value of said evolution variable to obtain a set of neural network parameters to provide an (n-1)-space solution at an initial value of said evolution variable;
modifying said set of neural network parameters for each of a plurality of intermediate value of said evolution variable between said initial value of said evolution variable and a final value of said evolution variable such that each modified set of neural network parameters is used to replace an immediately prior set of neural network parameters in said neural network to provide a respective (n-1)-space solution of said nonlinear partial differential equation at each corresponding intermediate value of said evolution variable using said neural network; and
modifying said set of neural network parameters for said final value of said evolution variable to provide a solution set of neural network parameters that is used to replace an immediately prior set of neural network parameters in said neural network to provide an (n-1)-space solution of said nonlinear partial differential equation at said final value of said evolution variable using said neural network,
wherein each of said modifying said set of neural network parameters for each intermediate value of said evolution variable and for said final value of said evolution variable is based on an evolution-variable-dependent property of said nonlinear partial differential equation without further training of said neural network.

5. A computer executable medium comprising non-transient computer-executable code for predicting a state of a system that is represented by a partial differential equation, said partial differential equation being a partial differential with respect to time, which, when executed by a computer, causes said computer to perform:
training a neural network for an initial state of said system to obtain a set of neural network parameters to provide a spatial representation of said system at an initial time;
modifying said set of neural network parameters for each of a plurality of intermediate times between said initial time and a prediction time such that each modified set of neural network parameters is used to replace an immediately prior set of neural network parameters in said neural network to provide a respective spatial representation of said system at each corresponding intermediate time using said neural network; and
modifying said set of neural network parameters for said prediction time to provide a prediction set of neural network parameters that is used to replace an immediately prior set of neural network parameters in said neural network to provide a predicted spatial representation of said system at said prediction time using said neural network,
wherein each of said modifying said set of neural network parameters for each intermediate time and for said prediction time is based on a time-dependent property of said partial differential equation without further training of said neural network, and
wherein said state of said system corresponds to said predicted spatial representation of said system at said prediction time.

6. The computer executable medium according to claim 5, wherein each neural network parameter of each set of neural network parameters is equal to a corresponding neural network parameter of the immediately prior set of neural network parameters plus a respective perturbation value determined from said partial differential equation.

7. The computer executable medium according to claim 6, wherein each said respective perturbation value is linear in a time difference with respect to said immediately prior set of neural network parameters.

8.-12. (canceled)
